(19) United States
(12) Patent Application Publication
(10) Pub. No.: US 2025/0318200 A1
(43) Pub. Date: Oct. 9, 2025

(54) SEMICONDUCTOR DEVICE AND METHODS OF FORMATION

(71) Applicant: Taiwan Semiconductor Manufacturing Company, Ltd., Hsinchu (TW)

(72) Inventors: Yun-Yan CHUNG, Hsinchu City (TW); Chao-Ching CHENG, Hsinchu City (TW); Bo-Jhih CHOU, Hsinchu City (TW); Wei-Sheng YUN, Taipei City (TW); Shao-Ming YU, Zhubei City (TW); Chen-Feng HSU, Hsinchu (TW); Huan-Sheng WEI, Taipei City (TW); Dhanyakumar Mahaveer SATHAIYA, Hsinchu (TW); Goutham ARUTCHELVAN, Hsinchu County (TW); Tung Ying LEE, Hsinchu City (TW); Iuliana RADU, Zhubei City (TW)

(21) Appl. No.: 18/626,960

(22) Filed: Apr. 4, 2024

(51) Int. Cl. H01L 29/786; H01L 29/06; H01L 29/417; H01L 29/423; H01L 29/66; H01L 29/775

(52) U.S. Cl. CPC H10D 30/6757; H10D 30/014; H10D 30/43; H10D 30/6729; H10D 30/6735; H10D 62/121; H10D 64/018

(57) ABSTRACT

One or more supporting dielectric layers are included under and/or on a nanostructure channel of a nanostructure transistor. The nanostructure transistor may be formed by forming a nanosheet stack that includes one or more channel layer stacks that are sandwiched between sacrificial layers. The nanostructure channel layer stacks may each include a nanostructure channel layer and one or more dielectric supporting layers under and/or on the nanostructure channel layer. The nanosheet stack is etched to define the nanostructure channels of the nanostructure transistor. An inner spacer process is performed to form inner spacers on sidewalls of the sacrificial layers between the nanostructure channel layer stacks, and source/drain contacts are then formed on sidewalls of the nanostructure channel layer stacks and on the inner spacers. The sacrificial layers are subsequently removed in a nanosheet release process and replaced with a metal gate structure and associated high-k dielectric layers.

### BACKGROUND

As semiconductor device manufacturing advances and technology processing nodes decrease in size, transistors may become affected by short channel effects (SCEs) such as hot carrier degradation, barrier lowering, and quantum confinement, among other examples. In addition, as the gate length of a transistor is reduced for smaller technology nodes, source/drain (S/D) electron tunneling increases, which increases the off current for the transistor (the current that flows through the channel of the transistor when the transistor is in an off configuration). Silicon (Si)/silicon germanium (SiGe) nanostructure transistors such as nanowires, nanosheets, and gate-all-around (GAA) devices are potential candidates to overcome short channel effects at smaller technology nodes. Nanostructure transistors are efficient structures that may experience reduced SCEs and enhanced carrier mobility relative to other types of transistors.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIGS. 2A and 2B are diagrams of an example implementation of a fin formation process described herein.

FIGS. 3A-3D are diagrams of an example implementation of an inner spacer formation process described herein.

FIG. 4 is a diagram of an example implementation of a source/drain contact layer formation process described herein.

FIG. 5 is a diagram of an example implementation of a source/drain plug layer formation process described herein.

FIG. 6 is a diagram of an example implementation of a nanosheet etch process described herein.

FIGS. 7A-7C are diagrams of an example implementation of a replacement gate (RPG) process described herein.

FIGS. 8A-8C are diagrams of an example implementation of an inner spacer formation process described herein.

FIGS. 9A-9C are diagrams of an example implementation of an inner spacer formation process described herein.

FIGS. 10A-10D are diagrams of an example implementation of an inner spacer formation process described herein.

FIG. 11 is a diagram of example components of a device described herein.

FIG. 12 is a flowchart of an example process associated with forming a semiconductor device described herein.

FIG. 13 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some cases, reducing geometric and dimensional properties of a fin field-effect transistor (finFET) may decrease a performance of the finFET. As an example, a likelihood of short channel effects such as drain-induced barrier lowering in a finFET may increase as finFET technology processing nodes decrease. Additionally or alternatively, a likelihood of electron tunneling and leakage in a finFET may increase as a gate length of the finFET decreases.

Nanostructure transistors (e.g., nanowire transistors, nanosheet transistors, gate-all-around (GAA) transistors, multi-bridge channel transistors, nanoribbon transistors, and/or other types of nanostructure transistors) may overcome one or more of the above-described drawbacks of finFETs. However, nanostructure transistors face fabrication challenges that can cause performance issues and/or device failures. For example, as the thicknesses of the nanostructure channels of a nanostructure transistor are reduced, the material(s) of the nanostructure channels may not provide sufficient mechanical strength to withstand sagging and/or other mechanical degradation. While replacing traditional nanostructure channel materials such as silicon (Si) with transition metal dichalcogenide (TMD) material may provide a greater Young's modulus and therefore greater mechanical strength at nano-scale thickness for the nanostructure channels, the nanostructure channels of the nanostructure transistor may still experience mechanical failure due to exposure to external forces from subsequent semiconductor processing operations such as film patterning and/or nanosheet release, among other examples.

In some implementations described herein, one or more supporting dielectric layers are included under and/or on a nanostructure channel of a nanostructure transistor. The nanostructure transistor may be formed by forming a nanosheet stack that includes one or more channel layer stacks that are sandwiched between sacrificial layers. The nanostructure channel layer stacks may each include a nanostructure channel layer and one or more dielectric supporting layers under and/or on the nanostructure channel layer. The nanosheet stack is etched to define the nanostructure channels of the nanostructure transistor. An inner spacer process is performed to form inner spacers on sidewalls of the sacrificial layers between the nanostructure channel layer stacks, and source/drain contacts are then formed on sidewalls of the nanostructure channel layer stacks and on the inner spacers. The sacrificial layers are subsequently removed in a nanosheet release process and replaced with a metal gate structure and associated high-k dielectric layers.

The supporting dielectric layer(s) may increase the mechanical strength of the nanostructure channel, which enables advanced materials such as TMD materials to be used in the nanostructure channel. This enables two-dimensional nanostructure channels (e.g., nanostructure channels that are approximately one atom in thickness) to be realized in the nanostructure transistor. Additionally and/or alternatively, the supporting dielectric layer(s) may reduce the likelihood and/or magnitude of mechanical degradation of the nanostructure channel that might otherwise occur due to external forces from subsequent semiconductor processing operations such as film patterning and/or nanosheet release, among other examples. Thus, the supporting dielectric layer(s) may provide a greater process window (e.g., a greater temperature range, a greater mechanical stress range) for forming the nanostructure channel. The supporting dielectric layer(s) may also provide a substrate on which the high-k dielectric layers of the metal gate structure are deposited, which may decrease void formation and improve thin-film growth of the high-k dielectric layers, relative to forming the high-k dielectric layers only on the two-dimensional nanostructure channels. The supporting dielectric layer(s) may increase the structural strength of a vertical stack of nanostructure channels, thereby enabling a great quantity of nanostructure channels to be realized on a single vertical stack. The supporting dielectric layer(s) may also provide sufficient structural strength for the nanostructure channel to enable the nanostructure channel to extend laterally outward from the supporting dielectric layer(s), which may enable reduced contact resistance to be achieved between the nanostructure channel and a source/drain contact in that a greater contact area between the nanostructure channel and the source/drain contact can be achieved. Moreover, the process for forming the supporting dielectric layer(s) may be integrated with silicon (Si) processing operations.

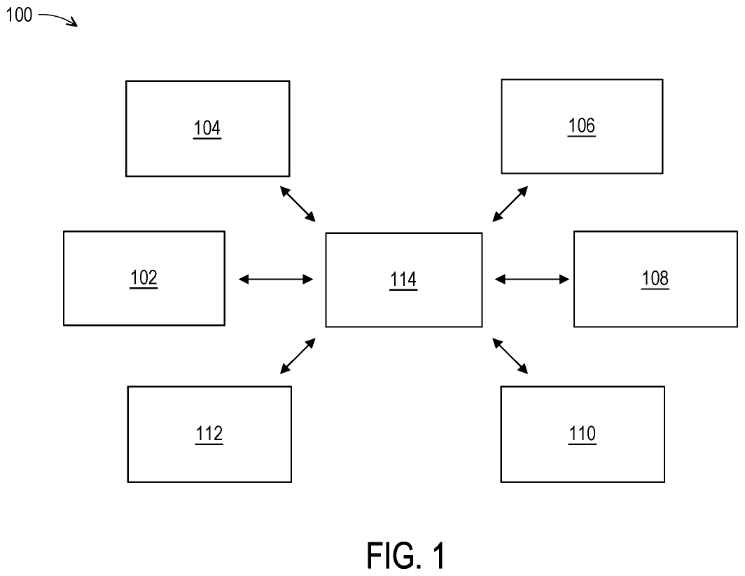

FIG. 1 is a diagram of an example environment 100 in which systems and/or methods described herein may be implemented. As shown in FIG. 1, the example environment 100 may include a plurality of semiconductor processing tools 102-112 and a wafer/die transport tool 114. The plurality of semiconductor processing tools 102-112 may include a deposition tool 102, an exposure tool 104, a developer tool 106, an etch tool 108, a planarization tool 110, a plating tool 112, and/or another type of semiconductor processing tool. The tools included in example environment 100 may be included in a semiconductor clean room, a semiconductor foundry, a semiconductor processing facility, and/or manufacturing facility, among other examples.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a high-density plasma CVD (HDP-CVD) tool, a sub-atmospheric CVD (SACVD) tool, a low-pressure CVD (LPCVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the deposition tool 102 includes an epitaxial tool that is configured to form layers and/or regions of a device by epitaxial growth. In some implementations, the example environment 100 includes a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that can be filled with an etchant, and the substrate is placed in the chamber for a particular time period to remove particular amounts of one or more portions of the substrate. In some implementations, the etch tool 108 etches one or more portions of the substrate using a plasma etch or a plasma-assisted etch, which may involve using an ionized gas to isotropically or directionally etch the one or more portions. In some implementations, the etch tool 108 includes a plasma-based asher to remove a photoresist material and/or another material.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

Wafer/die transport tool 114 includes a mobile robot, a robot arm, a tram or rail car, an overhead hoist transport (OHT) system, an automated materially handling system (AMHS), and/or another type of device that is configured to transport substrates and/or semiconductor devices between semiconductor processing tools 102-112, that is configured to transport substrates and/or semiconductor devices between processing chambers of the same semiconductor processing tool, and/or that is configured to transport substrates and/or semiconductor devices to and from other locations such as a wafer rack, a storage room, and/or the like. In some implementations, wafer/die transport tool 114 may be a programmed device that is configured to travel a particular path and/or may operate semi-autonomously or autonomously. In some implementations, the example environment 100 includes a plurality of wafer/die transport tools 114.

For example, the wafer/die transport tool 114 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 114 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations). In these implementations, the wafer/die transport tool 114 is configured to transport substrates and/or semiconductor devices between the processing chambers of the deposition tool 102 without breaking or removing a vacuum (or an at least partial vacuum) between the processing chambers and/or between processing operations in the deposition tool 102, as described herein.

As described herein, the semiconductor processing tools 102-112 may perform a combination of operations to form one or more portions of a nanostructure transistor. For example, one or more of the semiconductor processing tools 102-112 may be used to form, above a substrate of a semiconductor device, a layer stack that includes a plurality of sacrificial nanostructure layers and a plurality of nanostructure channel layer stacks, where the plurality of sacrificial nanostructure layers and the plurality of nanostructure channel layer stacks are arranged in a direction that is approximately perpendicular to the substrate, and where a nanostructure channel layer stack, of the plurality of nanostructure channel layer stacks, includes a nanostructure channel layer and at least one supporting dielectric layer between the nanostructure channel layer and a sacrificial nanostructure layer of the plurality of sacrificial nanostructure layers; etch the layer stack to form a fin structure that includes the plurality of sacrificial nanostructure layers and the plurality of nanostructure channel layer stacks; etch the plurality of sacrificial nanostructure layers to form cavities between the plurality of nanostructure channel layer stacks; form an inner spacer layer in the cavities and on exposed portions of the plurality of nanostructure channel layer stacks; perform a dry etch operation to etch the inner spacer layer to form inner spacers in the cavities, where the dry etch operation results in ends of the plurality of nanostructure channel layer stacks being exposed; and/or form a source/drain contact layer on the fin structure such that the source/drain contact layer is in contact with the ends of the plurality of nanostructure channel layer stacks, among other examples.

As another example, one or more of the semiconductor processing tools 102-112 may be used form, above a substrate of a semiconductor device, a layer stack that includes a plurality of sacrificial nanostructure layers and a plurality of nanostructure channel layer stacks, where the plurality of sacrificial nanostructure layers and the plurality of nanostructure channel layer stacks are arranged in a direction that is approximately perpendicular to the substrate, and where a nanostructure channel layer stack, of the plurality of nanostructure channel layer stacks, includes a nanostructure channel layer and at least one supporting dielectric layer between the nanostructure channel layer and a sacrificial nanostructure layer of the plurality of sacrificial nanostructure layers; etch the layer stack to form a fin structure that includes the plurality of sacrificial nanostructure layers and the plurality of nanostructure channel layer stacks; etch the plurality of sacrificial nanostructure layers to form cavities between the plurality of nanostructure channel layer stacks; form an inner spacer layer in the cavities and on exposed portions of the plurality of nanostructure channel layer stacks; etch the inner spacer layer to form inner spacers in the cavities, where etching the inner spacer layer results in ends of the plurality of nanostructure channel layer stacks being exposed, and where the inner spacers have a curved outer surface; and/or form a source/drain contact layer on the fin structure such that the source/drain contact layer is in contact with the ends of the plurality of nanostructure channel layer stacks, among other examples.

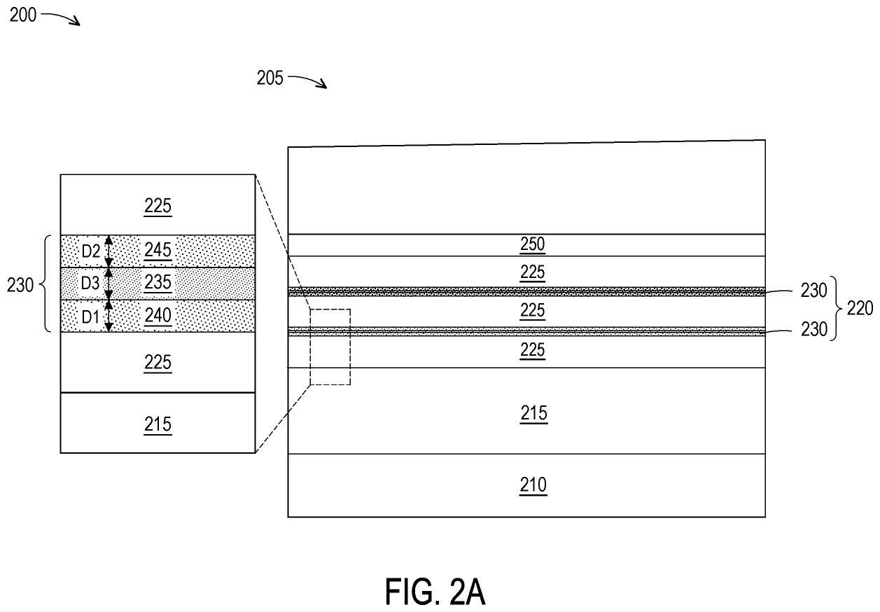

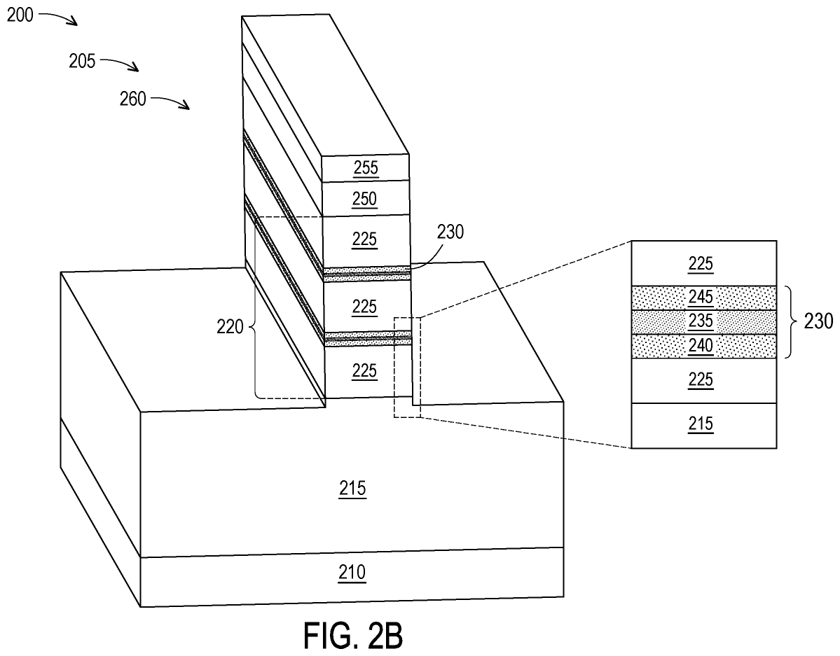

In some implementations, one or more of the semiconductor processing tools 102-112 may be used to perform one or more of the semiconductor processing operations described in connection with FIGS. 2A, 2B, 3A-3D, 4, 5, 6, 7A-7C, 8A-8C, 9A-9C, 10A-10D, 12, and/or 13, among other examples.

The number and arrangement of devices shown in FIG. 1 are provided as one or more examples. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) of the example environment 100 may perform one or more functions described as being performed by another set of devices of the example environment 100.

FIGS. 2A and 2B are diagrams of an example implementation 200 of a fin formation process described herein. The example implementation 200 includes an example of forming a fin structure for a semiconductor device 205 or a portion thereof. The fin structure may be formed as part of a process of forming one or more transistors on the semiconductor device 205. The one or more transistors may include nanostructure transistor(s) such as nanowire transistors, nanosheet transistors, gate-all-around (GAA) transistors, multi-bridge channel transistors, nanoribbon transistors, and/or other types of nanostructure transistors. The semiconductor device 205 may include one or more additional devices, structures, and/or layers not shown in FIGS. 2A and 2B. The semiconductor device 205 may include additional layers and/or dies formed on layers above and/or below the portion of the semiconductor device 205 shown in FIGS. 2A and 2B. Additionally, or alternatively, one or more additional semiconductor structures and/or semiconductor devices may be formed in a same layer of an electronic device that includes the semiconductor device 205.

FIG. 2A illustrates a perspective view of the semiconductor device 205. As shown in FIG. 2A, processing of the semiconductor device 205 may be performed in connection with a semiconductor substrate 210. The semiconductor substrate 210 may include a silicon (Si) substrate, a substrate formed of a material including silicon, a III-V compound semiconductor material substrate such as gallium arsenide (GaAs), a silicon on insulator (SOI) substrate, a germanium (Ge) substrate, a silicon germanium (SiGe) substrate, a silicon carbide (SiC) substrate, or another type of semiconductor substrate. The semiconductor substrate 210 may include various layers, including conductive or insulating layers formed on a semiconductor substrate. The semiconductor substrate 210 may include a compound semiconductor and/or an alloy semiconductor. The semiconductor substrate 210 may include various doping configurations to satisfy one or more design parameters. For example, different doping profiles (e.g., n-wells, p-wells) may be formed on the semiconductor substrate 210 in regions designed for different device types (e.g., p-type metal-oxide semiconductor (PMOS) nanostructure transistors, n-type metal-oxide semiconductor (NMOS) nanostructure transistors). The suitable doping may include ion implantation of dopants and/or diffusion processes. Further, the semiconductor substrate 210 may include an epitaxial layer (epi-layer), may be strained for performance enhancement, and/or may have other suitable enhancement features. The semiconductor substrate 210 may include a portion of a semiconductor wafer on which other semiconductor devices are formed.

As further shown in FIG. 2A, an isolation layer 215 is formed on the semiconductor substrate 210. The isolation layer 215 may provide electrical isolation between the transistor(s) of the semiconductor device 205 and the semiconductor substrate 210, which may reduce current leakage into the semiconductor substrate 210 and increase the operating efficiency of the transistor(s). The isolation layer 215 may include one or more electrically insulating materials, such as one or more dielectric materials. For example, the isolation layer 215 may include a silicon oxide (SiOₓ such as SiO₂), a silicon nitride (SiₓN_{y} such as Si₃N₄), a silicon oxynitride (SiON), fluoride-doped silicate glass (FSG), an aluminum oxide (AlₓO_{y} such as Al₂O₃), a hafnium oxide (HfOₓ such as HfO₂), a low dielectric constant (low-k) dielectric material, a high dielectric constant (high-k) dielectric material, and/or another suitable insulating material. A deposition tool 102 may be used to deposit the isolation layer 215 using a PVD technique, an ALD technique, a CVD technique, an oxidation technique, another type of deposition technique described in connection with FIG. 1, and/or another suitable deposition technique. The isolation layer 215 may be deposited in one or more deposition operations. In some implementations, a planarization tool 110 may be used to planarize the isolation layer 215 after the isolation layer 215 is deposited.

As further shown in FIG. 2A, a layer stack 220 is formed on the isolation layer 215. The layer stack 220 includes a plurality of alternating layers that are arranged in a direction that is approximately perpendicular to the semiconductor substrate 210. For example, the layer stack 220 includes vertically alternating layers of sacrificial nanostructure layers 225 and channel layer stacks 230 above the semiconductor substrate 210. The quantity of the sacrificial nanostructure layers 225 and the quantity of the channel layer stacks 230 illustrated in FIG. 2A are examples, and other quantities of the sacrificial nanostructure layers 225 and the channel layer stacks 230 are within the scope of the present disclosure.

The sacrificial nanostructure layers 225 include a first material composition, and the channel layer stacks 230 include a second material composition. In some implementations, the first material composition and the second material composition are the same material composition. In some implementations, the first material composition and the second material composition are different material compositions. As an example, the sacrificial nanostructure layers 225 may include silicon nitride (SiₓN_{y}), and the channel layer stacks 230 may each include a combination of nanostructure layers that include a silicon oxide (SiOₓ) and/or one or more TMD materials. In some implementations, the first material composition and the second material composition have different oxidation rates and/or etch selectivity, which enables the sacrificial nanostructure layers 225 to be subsequently removed in a nanosheet release operation with minimal to no removal of the material of the channel layer stacks 230. Other examples of materials for the sacrificial nanostructure layers 225 include a silicon oxide (SiOₓ), silicon carbonitride (SiCN), and/or silicon germanium (SiGe), among other examples.

As shown in a detailed view of the channel layer stack 230 in FIG. 2A, each channel layer stack 230 may include a nanostructure channel layer 235 and at least one supporting dielectric layer, such as a bottom supporting dielectric layer 240 under the nanostructure channel layer 235 and/or a top supporting dielectric layer 245 on the nanostructure channel layer 235. In some implementations, only a bottom supporting dielectric layer 240 is included between a nanostructure channel layer 235 and an underlying sacrificial nanostructure layer 225, and a top supporting dielectric layer 245 is omitted from the semiconductor device 205. In these implementations, the top surface of the nanostructure channel layer 235 may be in direct physical contact with a sacrificial nanostructure layer 225 above the nanostructure channel layer 235. In some implementations, only a top supporting dielectric layer 245 is included between a nanostructure channel layer 235 and a sacrificial nanostructure layer 225 above the nanostructure channel layer 235, and the bottom supporting dielectric layer 240 is omitted from the semiconductor device 205. In these implementations, the bottom surface of the nanostructure channel layer 235 may be in direct physical contact with a sacrificial nanostructure layer 225 under the nanostructure channel layer 235.

The supporting dielectric layer(s) may provide increased mechanical strength for the nanostructure channel layer 235, which may enable advanced materials such as TMDs to be used in the nanostructure channel layer 235. This enables two-dimensional nanostructure channels (e.g., nanostructure channels that are one atom in thickness) to be realized in the transistor(s) of the semiconductor device 205. Additionally and/or alternatively, the supporting dielectric layer(s) may reduce the likelihood and/or magnitude of mechanical degradation of the nanostructure channel layer 235 that might otherwise occur due to external forces from subsequent semiconductor processing operations such as film patterning and/or nanosheet release to remove the sacrificial nanostructure layers 225, among other examples.

The nanostructure channel layer 235 may include one or more semiconductor materials such as silicon (Si), silicon germanium (SiGe), and/or germanium (Ge), among other examples. Additionally and/or alternatively, the nanostructure channel layer 235 may include one or more TMD materials such as molybdenum sulfide (MoS₂), tungsten sulfide (WS₂), and/or tungsten selenide (WSe₂), among other examples.

The bottom supporting dielectric layer 240 and/or the top supporting dielectric layer 245 may include one or more dielectric materials such as a silicon oxide (SiOₓ such as SiO₂), a silicon nitride (SiₓN_{y} such as Si₃N₄), a silicon oxynitride (SiON), fluoride-doped silicate glass (FSG), an aluminum oxide (AlₓO_{y} such as Al₂O₃), a hafnium oxide (HfOₓ such as HfO₂), a low dielectric constant (low-k) dielectric material, a high dielectric constant (high-k) dielectric material, and/or another suitable insulating material. Additionally and/or alternatively, a nanostructured two-dimensional insulating material (e.g., an insulating material having a one-atom-thick crystalline structure) such as boron nitride (BN) may be used for the bottom supporting dielectric layer 240 and/or the top supporting dielectric layer 245. In some implementations, the bottom supporting dielectric layer 240 and the top supporting dielectric layer 245 include a same dielectric material and/or a same material composition. In some implementations, the bottom supporting dielectric layer 240 and the top supporting dielectric layer 245 include different dielectric materials and/or different material compositions.

Various techniques may be used to form a channel layer stack 230 on a sacrificial nanostructure layer 225. For example, a bottom supporting dielectric layer 240 of the channel layer stack 230 may be deposited or transferred onto the sacrificial nanostructure layer 225, a nanostructure channel layer 235 of the channel layer stack 230 may be deposited or transferred onto the bottom supporting dielectric layer 240, and a top supporting dielectric layer 245 of the channel layer stack 230 may be deposited or transferred onto the nanostructure channel layer 235. Another sacrificial nanostructure layer 225 may be deposited on the top supporting dielectric layer 245.

As another example, the bottom supporting dielectric layer 240 may be omitted, and the nanostructure channel layer 235 may be deposited or transferred onto the underlying sacrificial nanostructure layer 225. A top supporting dielectric layer 245 of the channel layer stack 230 may be deposited or transferred onto the nanostructure channel layer 235, and another sacrificial nanostructure layer 225 may be deposited on the top supporting dielectric layer 245.

As another example, the bottom supporting dielectric layer 240 may be deposited or transferred onto the underlying sacrificial nanostructure layer 225, the nanostructure channel layer 235 may be deposited or transferred onto the bottom supporting dielectric layer 240, and another sacrificial nanostructure layer 225 may be deposited on the top supporting dielectric layer 245 (with the top supporting dielectric layer 245 omitted).

A deposition tool 102 may be used to deposit the sacrificial nanostructure layers 225 of the layer stack 220 using a PVD technique, an ALD technique, a CVD technique, an oxidation technique, another type of deposition technique described in connection with FIG. 1, and/or another suitable deposition technique. The sacrificial nanostructure layers 225 of the layer stack 220 may each be deposited in one or more deposition operations.

In some implementations, a deposition tool 102 is used to deposit the bottom supporting dielectric layers 240 and/or the top supporting dielectric layers 245 of the layer stack 220 using a PVD technique, an ALD technique, a CVD technique, an oxidation technique, another type of deposition technique described in connection with FIG. 1, and/or another suitable deposition technique. The bottom supporting dielectric layers 240 and/or the top supporting dielectric layers 245 of the layer stack 220 may each be deposited in one or more deposition operations. In some implementations, the bottom supporting dielectric layers 240 and/or the top supporting dielectric layers 245 of the layer stack 220 are grown on a sacrificial substrate to have a particular crystalline structure (e.g., such as in the case for two-dimensional boron nitride) and then transferred to the semiconductor device 205 to form the layer stack 220.

In some implementations, a deposition tool 102 is used to deposit the nanostructure channel layers 235 of the layer stack 220 using a PVD technique, an ALD technique, a CVD technique, an oxidation technique, another type of deposition technique described in connection with FIG. 1, and/or another suitable deposition technique. The nanostructure channel layers 235 of the layer stack 220 may each be deposited in one or more deposition operations. In some implementations, the nanostructure channel layers 235 of the layer stack 220 are grown on a sacrificial substrate (such as a sapphire substrate or an aluminum oxide (Al₂O₃) substrate) to have a particular crystalline structure (e.g., such as in the case for a two-dimensional TMD nanostructure channel layer 235) and then transferred to the semiconductor device 205 to form the layer stack 220. The nanostructure channel layers 235 may be grown to be one layer thick, meaning that the nanostructure channel layers 235 are each one atomic layer of TMD material.

As further shown in the detailed view of the channel layer stack 230, a bottom supporting dielectric layer 240 may have a dimension D1 corresponding to a thickness of the bottom supporting dielectric layer 240. In some implementations, the dimension D1 is included in a range of approximately 1 nanometer to approximately 3 nanometers. If the dimension D1 is less than approximately 1 nanometers, the deposition uniformity of the bottom supporting dielectric layer 240 may not be controllable, and voids and/or other discontinuities may occur in the bottom supporting dielectric layer 240. If the dimension D1 is greater than approximately 3 nanometers, the thickness of the bottom supporting dielectric layer 240 may be too great to enable a high density of transistors to be formed on the semiconductor device 205. If the dimension D1 is included in the range of approximately 1 nanometer to approximately 3 nanometers, a continuous thin film may be formed for the bottom supporting dielectric layer 240 with minimal to no voids or other discontinuities, while enabling a high density of transistors to be formed on the semiconductor device 205. However, other values for the dimension D1, and ranges other than approximately 1 nanometer to approximately 3 nanometers, are within the scope of the present disclosure.

As further shown in the detailed view of the channel layer stack 230, a top supporting dielectric layer 245 may have a dimension D2 corresponding to a thickness of the top supporting dielectric layer 245. In some implementations, the dimension D2 is included in a range of approximately 1 nanometer to approximately 3 nanometers. If the dimension D2 is less than approximately 1 nanometers, the deposition uniformity of the top supporting dielectric layer 245 may not be controllable, and voids and/or other discontinuities may occur in the top supporting dielectric layer 245. If the dimension D2 is greater than approximately 3 nanometers, the thickness of the top supporting dielectric layer 245 may be too great to enable a high density of transistors to be formed on the semiconductor device 205. If the dimension D2 is included in the range of approximately 1 nanometer to approximately 3 nanometers, a continuous thin film may be formed for the top supporting dielectric layer 245 with minimal to no voids or other discontinuities, while enabling a high density of transistors to be formed on the semiconductor device 205. However, other values for the dimension D2, and ranges other than approximately 1 nanometer to approximately 3 nanometers, are within the scope of the present disclosure.

As further shown in the detailed view of the channel layer stack 230, a nanostructure channel layer 235 may have a dimension D3 corresponding to a thickness of the nanostructure channel layer 235. In some implementations, the dimension D3 corresponds to a one-layer-thick nanostructure channel layer 235 (e.g., a one-atom-thick layer of TMD material). In some implementations, the dimension D3 is greater than or equal to approximately 0.5 nanometers, and less than approximately 1 nanometer. However, other values and ranges for the dimension D3 are within the scope of the present disclosure.

As further shown in FIG. 2A, one or more additional layers may be formed over and/or on the layer stack 220. For example, a hard mask (HM) layer 250 may be formed over and/or on the layer stack 220 (e.g., on the top-most sacrificial nanostructure layer 225 of the layer stack 220). The hard mask layer 250 may include a silicon nitride (SiₓN_{y}), a silicon oxide (SiOₓ), and/or another dielectric material. A deposition tool 102 may be used to deposit the hard mask layer 250 using a PVD technique, an ALD technique, a CVD technique, an oxidation technique, another type of deposition technique described in connection with FIG. 1, and/or another suitable deposition technique. The hard mask layer 250 may be deposited in one or more deposition operations. In some implementations, a planarization tool 110 may be used to planarize the hard mask layer 250 after the hard mask layer 250 is deposited.

As shown in FIG. 2B, another hard mask layer 255 may be formed over and/or on the hard mask layer 250. The hard mask layer 255 may include one or more metal materials such as tungsten (W), cobalt (Co), ruthenium (Ru), titanium (Ti), aluminum (Al), copper (Cu), gold (Au), aluminum (Al), an alloy thereof, among other examples of metals. A deposition tool 102 and/or a plating tool 112 may be used to deposit the hard mask layer 250 using a PVD technique, an ALD technique, a CVD technique, an electroplating technique, another type of deposition technique described in connection with FIG. 1, and/or another suitable deposition technique. The hard mask layer 255 may be deposited in one or more deposition operations. In some implementations, a planarization tool 110 may be used to planarize the hard mask layer 255 after the hard mask layer 255 is deposited.

As further shown in FIG. 2B, the hard mask layers 250 and 255 are used to pattern the layer stack 220 to form a fin structure 260 from the layer stack 220. For example, a pattern may be formed in the hard mask layers 250 and 255, and the pattern in the hard mask layers 250 and 255 may be used to etch the layer stack 220 to form the fin structure 260 above the isolation layer 215. The etching of the layer stack 220 may stop on the isolation layer 215; however, a portion of the isolation layer 215 may be removed during the etching of the layer stack 220 (this is referred to as over-etching) to ensure that the layer stack 220 is fully etched through.

In some implementations, a pattern in a photoresist layer is used to etch the hard mask layers 250 and/or 255 to transfer the pattern to the hard mask layers 250 and/or 255. In these implementations, the deposition tool 102 may be used to form the photoresist layer on the hard mask layer 255. The exposure tool 104 may be used to expose the photoresist layer to a radiation source to pattern the photoresist layer. The developer tool 106 may be used to develop and remove portions of the photoresist layer to expose the pattern. The etch tool 108 may be used to etch the hard mask layers 250 and/or 255, based on the pattern, to transfer the pattern to the hard mask layers 250 and/or 255. In some implementations, the pattern is transferred to the hard mask layer 255 using the photoresist layer, and an etch tool 108 is used to transfer the pattern from the hard mask layer 255 to the hard mask layer 250. In some implementations, the pattern is transferred to the hard mask layers 250 and 255 using the photoresist layer.

An etch tool 108 may be used to etch the layer stack 220 based on the pattern in the hard mask layers 250 and 255 to form the fin structure 260 in one or more etch operations. In some implementations, the etch operation(s) include a dry etch operation such as a plasma etch operation. In some implementations, the etch operation(s) include a wet chemical etch operation and/or another type of etch operation. In some implementations, a plurality of etch operations are performed to cyclically etch the layer stack 220 to achieve sidewalls for the fin structure 260 that are approximately orthogonal to a surface of the semiconductor substrate 210. In some implementations, a photoresist removal tool may be used to remove the remaining portions of the photoresist layer (e.g., using a chemical stripper, plasma ashing, and/or another technique). In some implementations, a liftoff process is alternatively used to pattern the hard mask layers 250 and 255.

As shown in FIG. 2B, the fin structure 260 extends above the semiconductor substrate 210 and above the isolation layer 215. The fin structure 260 includes remaining portions of the layer stack 220 that were not removed during etching of the layer stack 220. The remaining portions include portions of sacrificial nanostructure layers 225 of the layer stack 220, and portions of the channel layer stacks 230 (including portions of the bottom supporting dielectric layers 240 and/or portions of the top supporting dielectric layers 245, and portions of the nanostructure channel layers 235).

As indicated above, FIGS. 2A and 2B are provided as an example. Other examples may differ from what is described with regard to FIGS. 2A and 2B. Example implementation 200 may include additional operations, fewer operations, different operations, and/or a different order of operations than those described in connection with FIGS. 2A and 2B.

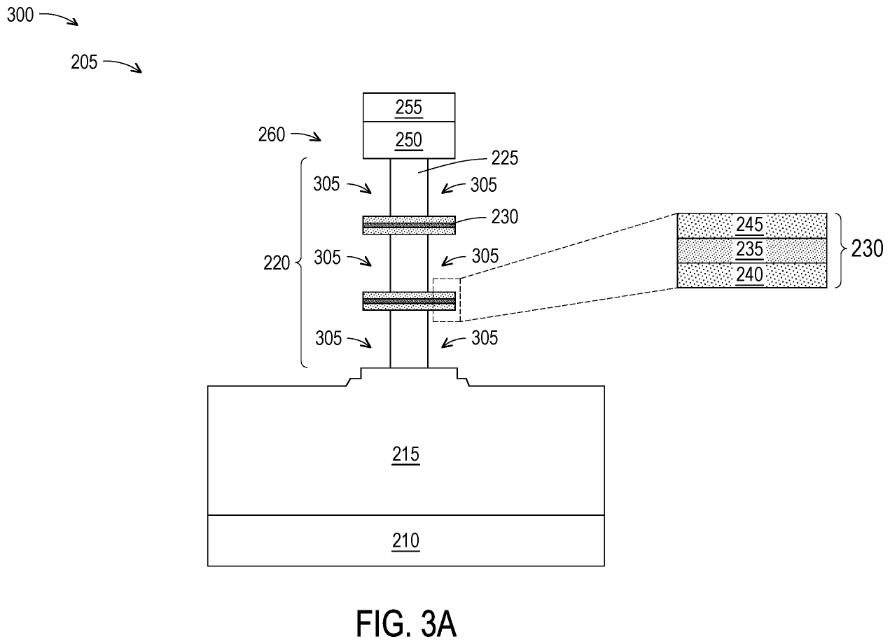

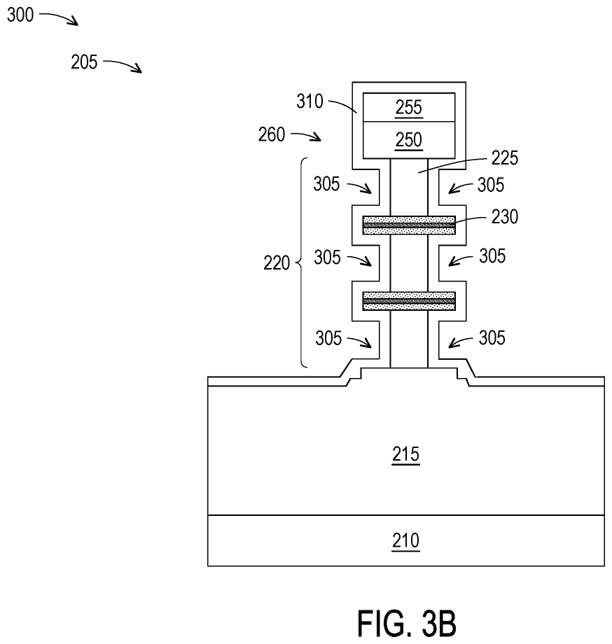

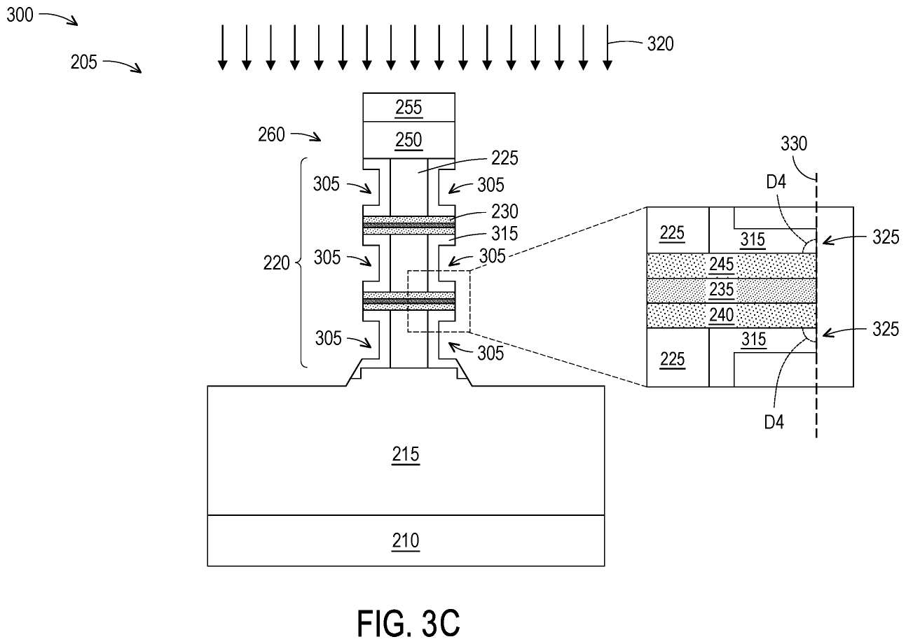

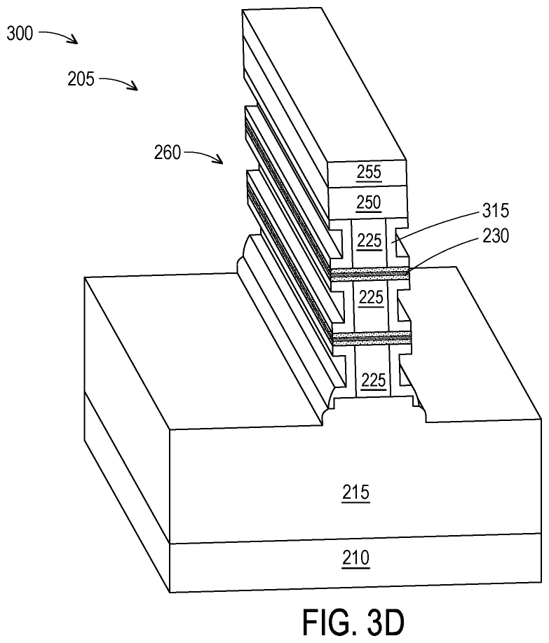

FIGS. 3A-3D are diagrams of an example implementation 300 of an inner spacer formation process described herein. The example implementation 300 includes an example of forming inner spacers on the fin structure 260. The inner spacers are formed to provide electrical isolation between a gate structure of a transistor of the semiconductor device 205 and source/drain contact layers of the transistor, which reduces the likelihood of electrical shorting between the gate structure and the source/drain contact layers. The inner spacers may also reduce parasitic capacitance in the transistor and may protect the source/drain contact layers from being etched in a nanosheet release operation to remove sacrificial nanostructure layers 225. In some implementations, the operations described in connection with the example implementation 300 are performed after the processes described in connection with FIGS. 2A and 2B.

As shown in FIG. 3A, the sacrificial nanostructure layers 225 of the fin structure 260 are laterally etched (e.g., in a direction that is approximately parallel to the top surface of the semiconductor substrate 210) in an etch operation, thereby forming cavities 305 between portions of the channel layer stacks 230. In particular, an etch tool 108 is used to laterally etch ends of the sacrificial nanostructure layers 225 to form the cavities 305 between ends of the channel layer stacks 230. In some implementations, an etchant is used to etch sacrificial nanostructure layers 225, and the etchant may have a greater etch rate for the sacrificial nanostructure layers 225 than the etch rate for the channel layer stacks 230 so that minimal etching of the channel layer stacks 230 occurs. The formation of the cavities 305 results in the ends of the channel layer stacks 230 extending laterally outward from the sacrificial nanostructure layers 225.

As shown in FIG. 3B, an inner spacer layer 310 is conformally deposited along the sidewalls and the top of the fin structure 260. In particular, the inner spacer layer 310 conforms to the profile of the fin structure 260 such that the inner spacer layer 310 is formed as a thin film in the cavities 305 on the ends of the sacrificial nanostructure layers 225. The inner spacer layer 310 is also deposited on the exposed surfaces (e.g., top surfaces, bottom surfaces, side surfaces, end surfaces) of the channel layer stacks 230 that extend laterally outward from the sacrificial nanostructure layers 225. A deposition tool 102 may be used to deposit the inner spacer layer 310 using a CVD technique, a PVD technique, and ALD technique, and/or another deposition technique.

In some implementations, the inner spacer layer 310 includes a silicon nitride (SiₓN_{y}), a silicon oxide (SiOₓ), a silicon oxynitride (SiON), a silicon oxycarbide (SiOC), a silicon carbon nitride (SiCN), a silicon oxycarbonnitride (SiOCN), and/or another dielectric material. In some implementations, the inner spacer layer 310 includes a metal-based oxide material such as tungsten oxide (WOₓ), molybdenum oxide (MoOₓ), and/or another metal-based oxide material.

As shown in FIG. 3C, the inner spacer layer 310 is partially removed such that remaining portions of the inner spacer layer 310 correspond to inner spacers 315 in the cavities 305. An etch tool 108 may be used to perform an etch operation to partially remove the inner spacer layer 310 to form the inner spacers 315. The etch operation 320 may include a highly directional etch to selectively remove the inner spacer layer 310 from the ends of the channel layer stacks 230 and not from (or minimally from) the cavities 305. In particular, the highly directional etch 320 may include a vertical etch in which the inner spacer layer 310 is primarily etched in a direction that is approximately perpendicular to the surface of the semiconductor substrate 210. A dry etch technique, such as a plasma-based etch technique, may be used to achieve the vertical etch. For example, a pressure in the etch tool 108, a bias voltage for the plasma, and/or another parameter of the etch tool 108 may be selected to achieve the vertical etch.

As shown in a detailed view in FIG. 3C, ends 325 of the inner spacers 315 may be approximately co-planar with ends of the channel layer stack 230 (e.g., with ends of the nanostructure channel layer 235, the bottom supporting dielectric layer 240, and/or the top supporting dielectric layer 245) in that the ends 325 of the inner spacers 315 and the ends of the channel layer stack 230 are approximately in a same horizontal plane 330. The ends 325 of the inner spacers 315 may have an angle (indicated in FIG. 3C as dimension D4) relative to the nanostructure channel layer 235, the bottom supporting dielectric layer 240, and/or the top supporting dielectric layer 245 that is approximately 90 degrees (e.g., approximately 85-95 degrees). However, other values for the angle are within the scope of the present disclosure.

As shown in a perspective view of the fin structure 260 in FIG. 3D, the inner spacers 315 may have an approximately C-shaped cross-sectional profile. The inner spacers 315 may extend along the fin structure 260. An inner spacer 315 may include a segment that is located on a sidewall of a sacrificial nanostructure layer 225, a segment that is located on a top surface of a channel layer stack 230, and a segment that is located on a bottom surface of another channel layer stack 230.

As indicated above, FIGS. 3A-3D are provided as examples. Other examples may differ from what is described with regard to FIGS. 3A-3D. Example implementation 300 may include additional operations, fewer operations, different operations, and/or a different order of operations than those described in connection with FIGS. 3A-3D.

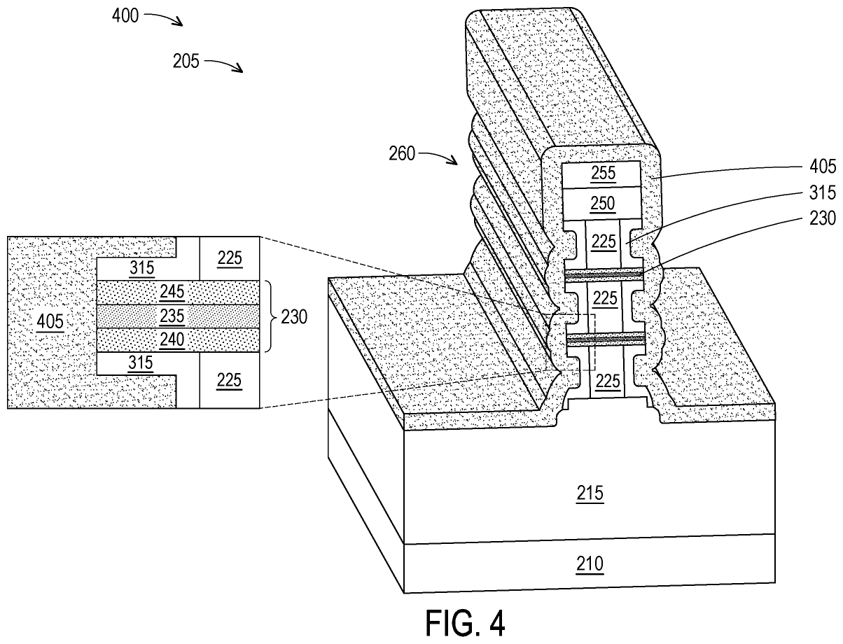

FIG. 4 is a diagram of an example implementation 400 of a source/drain contact layer formation process described herein. The example implementation 400 includes an example of forming a source/drain contact layer on the fin structure 260 of the semiconductor device 205. In some implementations, the operations described in connection with the example implementation 400 are performed after the processes described in connection with FIGS. 2A-3D.

As shown in FIG. 4, a source/drain contact layer 405 is formed on the fin structure 260. The source/drain contact layer 405 fills in the remaining areas of the cavities 305 in which the inner spacers 315 were formed. The source/drain contact layer 405 is also formed on the exposed ends of the channel layer stacks 230, including on the exposed ends of the nanostructure channel layers 235, on the exposed ends of the bottom supporting dielectric layers 240, and/or on the exposed ends of top supporting dielectric layers 245.

A deposition tool 102 and/or a plating tool 112 may be used to deposit the source/drain contact layer 405 using a PVD technique, an ALD technique, a CVD technique, an electroplating technique, another type of deposition technique described in connection with FIG. 1, and/or another suitable deposition technique. The source/drain contact layer 405 may be deposited in one or more deposition operations. In some implementations, a deposition technique having a high step coverage is used to deposit the source/drain contact layer 405. “Step coverage” refers to the coverage uniformity on surfaces of different heights, angles, and/or shapes. A deposition technique having a high step coverage is a deposition technique that may achieve a highly uniform deposition rate on surfaces of the fin structure 260 that are located at different heights and/or angles, and that have shapes. This enables the source/drain contact layer 405 to be formed in the cavities 305 as well as on the ends of the channel layer stacks 230, while achieving a continuous layer for the source/drain contact layer 405 with minimal to no voids or other discontinuities in the source/drain contact layer 405.

In some implementations, the source/drain contact layer 405 includes one or more metal materials, one or more metal alloys, one or more semi-metals, one or more semi-metallic TMD materials, a combination thereof, and/or another suitable material. For example, the source/drain contact layer 405 may include a nitrogen-rich transition metal nitride such as Mo₅N₆. As another example, the source/drain contact layer 405 may include platinum selenide (PtSe₂), titanium (Ti), titanium nitride (TiN), tungsten (W), cobalt (Co), bismuth (Bi), and/or antimony (Sb), among other examples.

As indicated above, FIG. 4 is provided as an example. Other examples may differ from what is described with regard to FIG. 4. Example implementation 400 may include additional operations, fewer operations, different operations, and/or a different order of operations than those described in connection with FIG. 4.

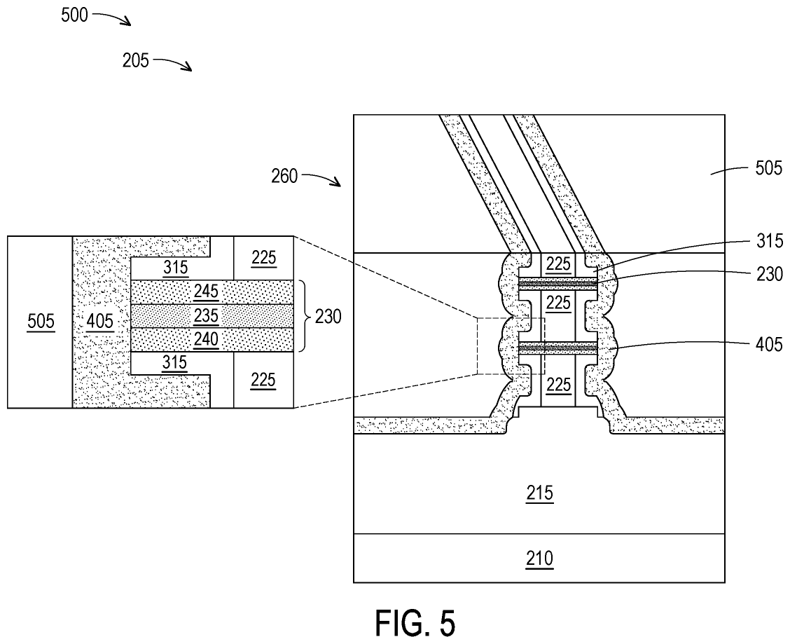

FIG. 5 is a diagram of an example implementation 500 of a source/drain plug layer formation process described herein. In some implementations, the operations described in connection with the example implementation 500 are performed after the processes described in connection with FIGS. 2A-4.

As shown in FIG. 5, a source/drain plug layer 505 is formed on the source/drain contact layer 405. A deposition tool 102 and/or a plating tool 112 may be used to deposit the source/drain plug layer 505 using a PVD technique, an ALD technique, a CVD technique, an electroplating technique, another type of deposition technique described in connection with FIG. 1, and/or another suitable deposition technique. The source/drain plug layer 505 may be deposited in one or more deposition operations. The source/drain plug layer 505 includes one or more metal materials, one or more metal alloys, one or more semi-metals, one or more semi-metallic TMD materials, a combination thereof, and/or another suitable material. For example, the source/drain plug layer 505 may include tungsten (W), cobalt (Co), copper (Cu), titanium (Ti), and/or ruthenium (Ru), among other examples.

In some implementations, one or more liners are deposited on the source/drain contact layer 405, and the source/drain plug layer 505 is deposited on the one or more liners. The one or more liners may include an adhesion liner to promote adhesion between the source/drain contact layer 405 and the source/drain plug layer 505, a barrier layer to inhibit migration of material of the source/drain plug layer 505 into surrounding layers, and/or another type of liner. Examples of materials for the one or more liners include nickel (Ni), titanium (Ti), titanium nitride (TiN), and/or tantalum nitride (TaN), among other examples.

As further shown in FIG. 5, the hard mask layers 250 and 255 are removed from the fin structure 260 of the semiconductor device 205. The hard mask layers 250 and 255 may be removed from the fin structure 260 after formation of the source/drain plug layer 505. Forming the source/drain plug layer 505 prior to removal of the hard mask layers 250 and 255 enables the removal of the hard mask layers 250 and 255 to result in formation of separate source/drain contact layers 405 on opposing sides of the fin structure 260 and separate source/drain plug layers 505 on opposing sides of the fin structure 260 without the use of additional masking layers. In other words, the removal of the hard mask layers 250 and 255 splits the source/drain contact layer 405 into separate source/drain contact layers 405 and splits the source/drain plug layer 505 into separate source/drain plug layers 505 without the use of additional masking layers to pattern the source/drain contact layer 405 and the source/drain plug layer 505. Thus, the formation of the source/drain contact layers 405 and the source/drain plug layers 505 is self-aligned. In this way, the source/drain contact layers 405 on opposing sides of the fin structure 260 are not in direct contact, and the source/drain plug layers 505 on opposing sides of the fin structure 260 are not in direct contact, which reduces the likelihood of electrical shorting.

A planarization tool 110 may be used to perform a planarization operation to remove the hard mask layers 250 and 255, as well as to remove excess material of source/drain contact layer 405 and of the source/drain plug layer 505 to form the separate source/drain contact layers 405 and the separate source/drain plug layers 505. The planarization operation may stop on the top-most sacrificial nanostructure layer 225 such that the top surface of the top-most sacrificial nanostructure layer 225 is exposed.

As indicated above, FIG. 5 is provided as an example. Other examples may differ from what is described with regard to FIG. 5. Example implementation 500 may include additional operations, fewer operations, different operations, and/or a different order of operations than those described in connection with FIG. 5.

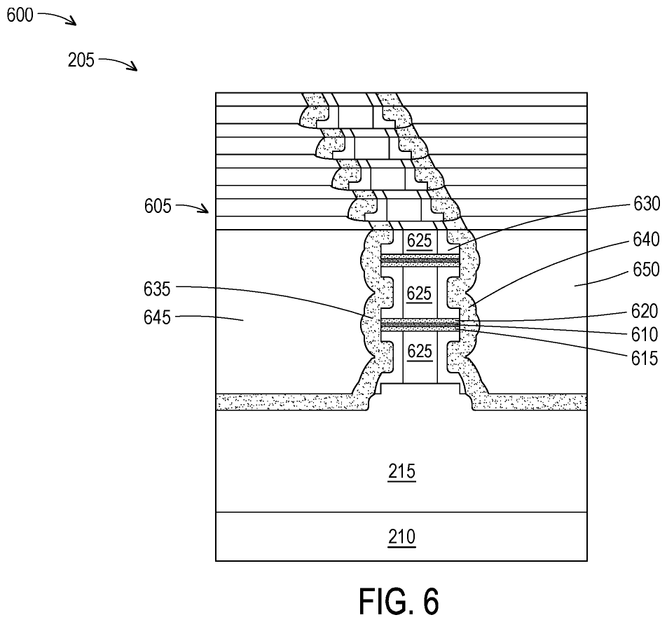

FIG. 6 is a diagram of an example implementation 600 of a nanosheet etch process described herein. The nanosheet etch process may be performed to etch the fin structure 260 and the associated source/drain contact layers 405 and source/drain plug layers 505 to define a plurality of nanostructure transistors 605. In some implementations, the operations described in connection with the example implementation 600 are performed after the processes described in connection with FIGS. 2A-5.

As shown in FIG. 6, the fin structure 260 is etched to define the nanostructure transistors 605. A nanostructure transistor 605 extends above the semiconductor substrate 210 and above the isolation layer 215. A nanostructure transistor 605 includes portions of the fin structure 260 such portions of channel layer stacks 230 (e.g., portions of the nanostructure channel layers 235, portions of the bottom supporting dielectric layers 240, portions of the top supporting dielectric layers 245), portion of the sacrificial nanostructure layers 225, and portions of the inner spacers 315. The portions of the nanostructure channel layers 235 correspond to nanostructure channels 610 of a nanostructure transistor 605. The portions of the bottom supporting dielectric layers 240 correspond to bottom supporting dielectric layers 615 of a nanostructure transistor 605. The portions of the top supporting dielectric layers 245 correspond to top supporting dielectric layers 620 of a nanostructure transistor 605. Portions of the sacrificial nanostructure layers 225 correspond to sacrificial structures 625 between the nanostructure channels 610. Portions of the inner spacers 315 correspond to inner spacers 630 between the nanostructure channels 610.

A bottom supporting dielectric layer 615 and a top supporting dielectric layer 620 may be vertically adjacent to a nanostructure channel 610 such that the nanostructure channel 610 is vertically between the bottom supporting dielectric layer 615 and the top supporting dielectric layer 620. In some implementations, the bottom supporting dielectric layer 615 and the top supporting dielectric layer 620 include a same dielectric material and/or a same material composition. In some implementations, the bottom supporting dielectric layer 615 and the top supporting dielectric layer 620 include different dielectric materials and/or different material compositions.

In some implementations, only a bottom supporting dielectric layer 615 is included between a nanostructure channel 610 and an underlying sacrificial structure 625, and a top supporting dielectric layer 620 is omitted from the semiconductor device 205. In these implementations, the top surface of the nanostructure channel 610 may be in direct physical contact with a sacrificial structure 625 above the nanostructure channel 610. In some implementations, only a top supporting dielectric layer 620 is included between a nanostructure channel 610 and a sacrificial structure 625 above the nanostructure channel 610, and the bottom supporting dielectric layer 615 is omitted from the semiconductor device 205. In these implementations, the bottom surface of the nanostructure channel 610 may be in direct physical contact with a sacrificial structure 625 under the nanostructure channel 610.

The source/drain contact layers 405 and the source/drain plug layers 505 are also etched in the nanosheet etch process to define source/drain contacts 635 and 640 on opposing sides of the nanostructure channels 610 of the nanostructure transistors 605, and to define source/drain plugs 645 and 650 on opposing sides of the nanostructure channels 610 of the nanostructure transistors 605. “Source/drain” may refer to a source or a drain, individually or collectively dependent upon the context. A source/drain contact 635 may be located on (and may be in contact with) first ends of the nanostructure channels 610 of a nanostructure transistor 605, and a source/drain contact 640 may be located on (and may be in contact with) second ends of the nanostructure channels 610 opposing the first ends. The source/drain contacts 635 and 640 may each have an approximately C-shaped cross-sectional profile. A source/drain plug 645 may be located on the source/drain contact 635, and a source/drain plug 650 may be located on the source/drain contact 640.

In some implementations, one or more hard mask layers may be formed (e.g., using a deposition tool 102) over and/or on the fin structure 260, the source/drain contact layer 405, and/or the source/drain plug layer 505. The one or more hard mask layers may be used to perform the nanosheet etch process to define the nanostructure transistors 605. For example, a dielectric hard mask layer and a metal hard mask layer, similar to the hard mask layer 250 and 255, respectively, may be formed. A pattern may be formed in the metal hard mask layer (e.g., using an etch tool 108 and/or a lift-off process) and then transferred to the dielectric hard mask layer (e.g., using an etch tool 108). The fin structure 260, the source/drain contact layer 405, and/or the source/drain plug layer 505 may be etched (e.g., using an etch tool 108) based on the pattern using a dry etch technique and/or another suitable etch technique. In some implementations, a plurality of etch operations are performed to cyclically etch the fin structure 260, the source/drain contact layer 405, and/or the source/drain plug layer 505 to achieve sidewalls for the nanostructure transistors 605 that are approximately orthogonal to a surface of the semiconductor substrate 210. The hard mask layers may be subsequently removed.

As indicated above, FIG. 6 is provided as an example. Other examples may differ from what is described with regard to FIG. 6. Example implementation 600 may include additional operations, fewer operations, different operations, and/or a different order of operations than those described in connection with FIG. 6.

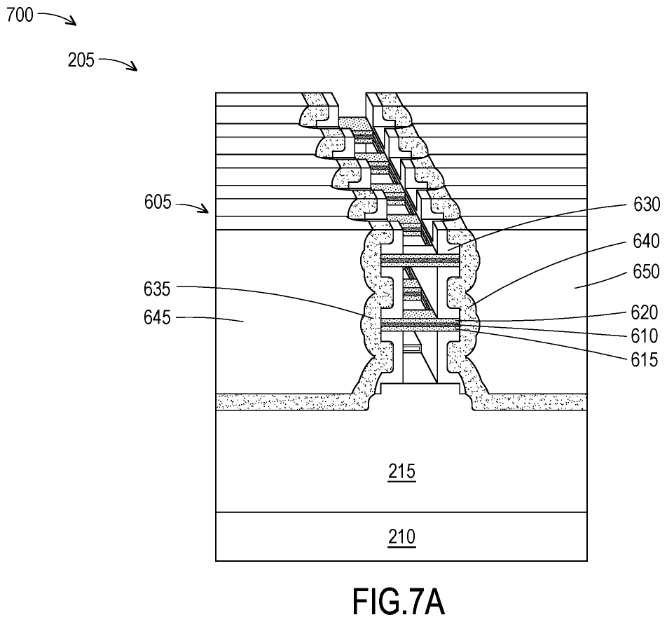

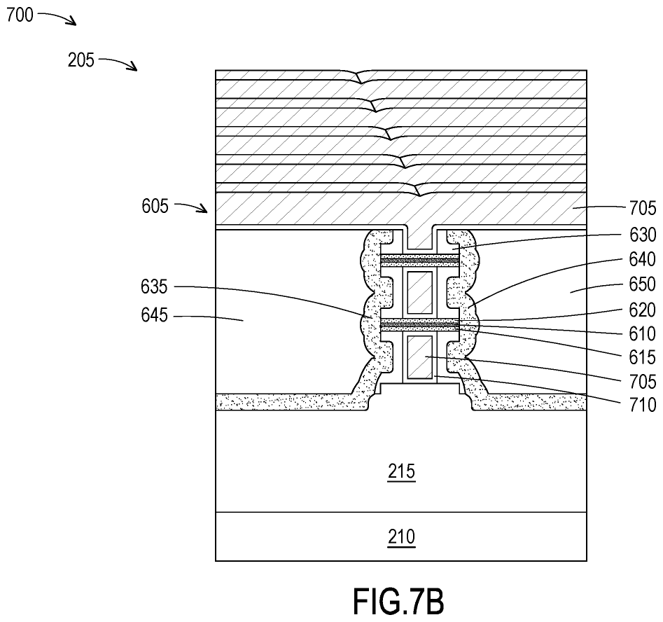

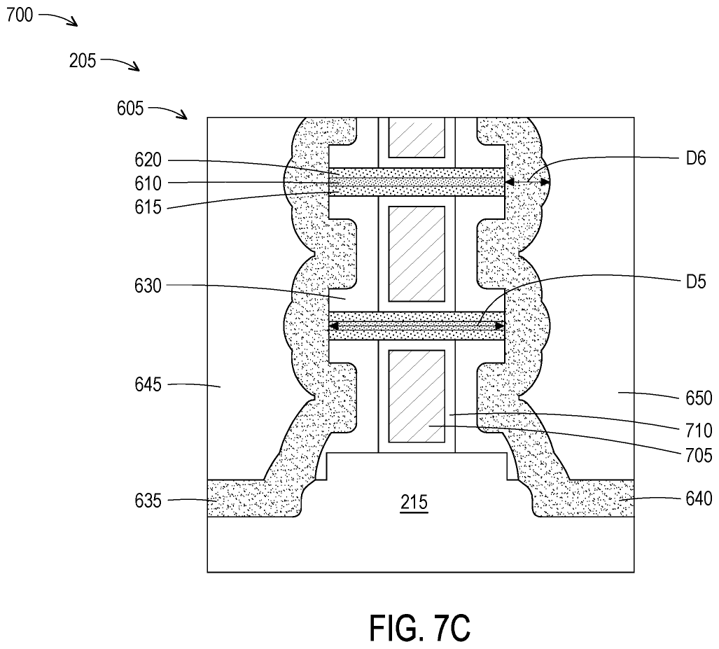

FIGS. 7A-7C are diagrams of an example implementation 700 of a replacement gate (RPG) process described herein. The example implementation 700 includes an example of a replacement gate process for replacing the sacrificial structures 625 with gate structures (e.g., replacement gate structures) of the nanostructure transistors 605 of the semiconductor device 205. In some implementations, the operations described in connection with the example implementation 700 are performed after the operations described in connection with FIGS. 3A-6.

As shown in FIG. 7A, a nanosheet release operation of the RPG process is performed to remove the sacrificial structures 625 from the nanostructure transistors 605. This results in the formation of openings between and around the nanostructure channels 610. The nanostructure release operation may include the use of an etch tool 108 to perform an etch operation to remove the sacrificial structures 625 based on a difference in etch selectivity between the material of the sacrificial structures 625 and the material of the nanostructure channels 610, and between the material of the sacrificial structures 625 and the material of the inner spacers 630. The inner spacers 630 may function as etch stop layers in the etch operation to protect the source/drain contacts 635 and 640 from being etched.

The etch operation to remove the sacrificial structures 625 may include an isotropic etch technique to etch the sacrificial structures 625 in a plurality of directions to fully remove the sacrificial structures 625. As an example, a wet etch technique may be used to remove the sacrificial structures 625. As another example, a hydrofluoric acid (HF) vapor etch technique may be used to remove the sacrificial structures 625. As another example, a fluorocarbon-based plasma etch technique may be used to remove the sacrificial structures 625. The fluorocarbon-based plasma etch technique may include the use of a carbon tetrafluoride (CF₄) etchant, in which carbon tetrafluoride radicals are used to etch the sacrificial structures 625.

As shown in FIG. 7B, the RPG operation continues where gate structures (e.g., replacement gate structures) 705 of the nanostructure transistors 605 are formed in the openings between and around the nanostructure channels 610 and between the inner spacers 630. The gate structures 705 wrap around at least three sides of the nanostructure channels 610. In particular, the gate structures 705 fill the areas between and around the nanostructure channels 610 that were previously occupied by the sacrificial structures 625 such that the gate structures 705 fully wrap around the nanostructure channels 610 and surround the nanostructure channels 610. The gate structures 705 may include metal gate structures that include one or more metals such as tungsten (W), cobalt (Co), ruthenium (Ru), titanium (Ti), an alloy thereof, among other examples of metals. Additionally and/or alternatively, the gate structures 705 may include one or more p-type work function metals, one or more n-type work function metals, and/or another type of work function metal.

Prior to formation of the gate structures 705, gate dielectric layers 710 of the nanostructure transistors 605 may be formed in the openings around the nanostructure channels 610. The gate structures 705 may be formed on the gate dielectric layers 710. The gate dielectric layers 710 include one or more dielectric materials, such as a silicon oxide (SiOₓ such as SiO₂), a silicon nitride (SiₓN_{y} such as Si₃N₄), an aluminum oxide (AlₓO_{y} such as Al₂O₃), a hafnium oxide (HfOₓ such as HfO₂), a zirconium oxide (ZrOₓ such as ZrO₂), a hafnium zirconium oxide (HfₓZr_{y}O_{z}), aluminum nitride (AiN), hafnium nitride (HfN), a high-k dielectric material, and/or another suitable dielectric material.

In some implementations, an interfacial layer (not shown) is also deposited (on the gate dielectric layers 710, prior to formation of the gate dielectric layers 710) prior to formation of the gate structures 705. The interfacial layer may include one or more dielectric materials such as a silicon oxide (SiOₓ such as SiO₂), a silicon nitride (SiₓN_{y} such as Si₃N₄), a silicon oxynitride (SiON), fluoride-doped silicate glass (FSG), an aluminum oxide (AlₓO_{y} such as Al₂O₃), a hafnium oxide (HfOₓ such as HfO₂), aluminum nitride (AiN), hafnium nitride (HfN), a low-k dielectric material, a high-k dielectric material, and/or another suitable insulating material. Additionally and/or alternatively, a nanostructured two-dimensional insulating material (e.g., an insulating material having a one-atom-thick crystalline structure) such as boron nitride (BN) may be used for the interfacial layer.

A deposition tool 102 may be used to deposit the gate dielectric layers 710 using a CVD technique, a PVD technique, an ALD technique, another deposition technique described above in connection with FIG. 1, and/or another suitable deposition technique. A deposition tool 102 may be used to deposit the interfacial layer using a CVD technique, a PVD technique, an ALD technique, another deposition technique described above in connection with FIG. 1, and/or another suitable deposition technique. A deposition tool 102 may be used to deposit the gate structures 705 using a CVD technique, a PVD technique, an ALD technique, another deposition technique described above in connection with FIG. 1, and/or another suitable deposition technique.

In some implementations, only a bottom supporting dielectric layer 615 is included between a nanostructure channel 610 and an underlying gate structure 705, and a top supporting dielectric layer 620 is omitted from the semiconductor device 205. In these implementations, the top surface of the nanostructure channel 610 may be in direct physical contact with a gate dielectric layer 710 between the nanostructure channel 610 and a gate structure 705 above the nanostructure channel 610. In some implementations, only a top supporting dielectric layer 620 is included between a nanostructure channel 610 and a gate structure 705 above the nanostructure channel 610, and the bottom supporting dielectric layer 615 is omitted from the semiconductor device 205. In these implementations, the bottom surface of the nanostructure channel 610 may be in direct physical contact with a gate dielectric layer 710 between the nanostructure channel 610 and a gate structure 705 under the nanostructure channel 610.

As shown in FIG. 7C, a planarization operation may be performed to planarize the gate structures 705 and/or to remove excess material from the gate structures 705. A planarization tool 110 may be used to perform the planarization operation.

As further shown in FIG. 7C, an example dimension of a nanostructure transistor 605 may include a channel length (corresponding to dimension D5 in FIG. 7C) of a nanostructure channel 610. “Channel length” refers to the length of the nanostructure channel 610 between the source/drain contacts 635 and 640. In some implementations, the channel length is included in a range of approximately 5 nanometers to approximately 20 nanometers. If the channel length is less than approximately 5 nanometers, the nanostructure transistor 605 may experience high current leakage and may be unable to be switched off. If the channel length is greater than approximately 20 nanometers, the size of the nanostructure transistor 605 may not enable a high density of transistors to be formed on the semiconductor device 205. If the channel length is included in the range of approximately 5 nanometers to approximately 20 nanometers, a low current leakage may be achieved for the nanostructure transistor 605, while enabling a high density of transistors to be formed on the semiconductor device 205. However, other values for the channel length, and ranges other than approximately 5 nanometers to approximately 20 nanometers, are within the scope of the present disclosure.

As further shown in FIG. 7C, another example dimension of a nanostructure transistor 605 may include a thickness (corresponding to dimension D6 in FIG. 7C) of a source/drain contact (e.g., of a source/drain contact 635, of a source/drain contact 640). In some implementations, the thickness is included in a range of approximately 5 nanometers to approximately 20 nanometers. If the thickness is less than approximately 5 nanometers, the nanostructure transistor 605 may experience high contact resistance, which may reduce the performance of the nanostructure transistor 605. If the thickness is greater than approximately 20 nanometers, the size of the nanostructure transistor 605 may not enable a high density of transistors to be formed on the semiconductor device 205. If the thickness is included in the range of approximately 5 nanometers to approximately 20 nanometers, a low contact resistance may be achieved for the nanostructure transistor 605, while enabling a high density of transistors to be formed on the semiconductor device 205. However, other values for the thickness, and ranges other than approximately 5 nanometers to approximately 20 nanometers are within the scope of the present disclosure.

As indicated above, FIGS. 7A-7C are provided as an example. Other examples may differ from what is described with regard to FIGS. 7A-7C. Example implementation 700 may include additional operations, fewer operations, different operations, and/or a different order of operations than those described in connection with FIGS. 7A-7C.

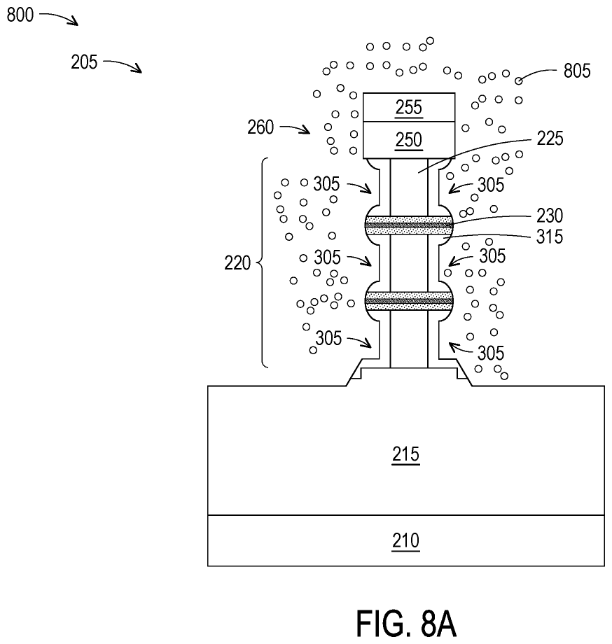

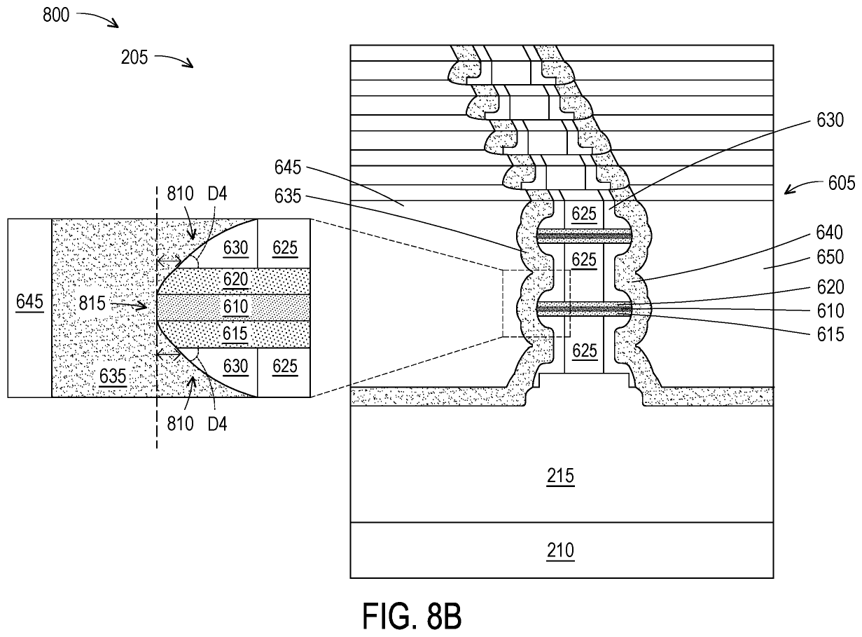

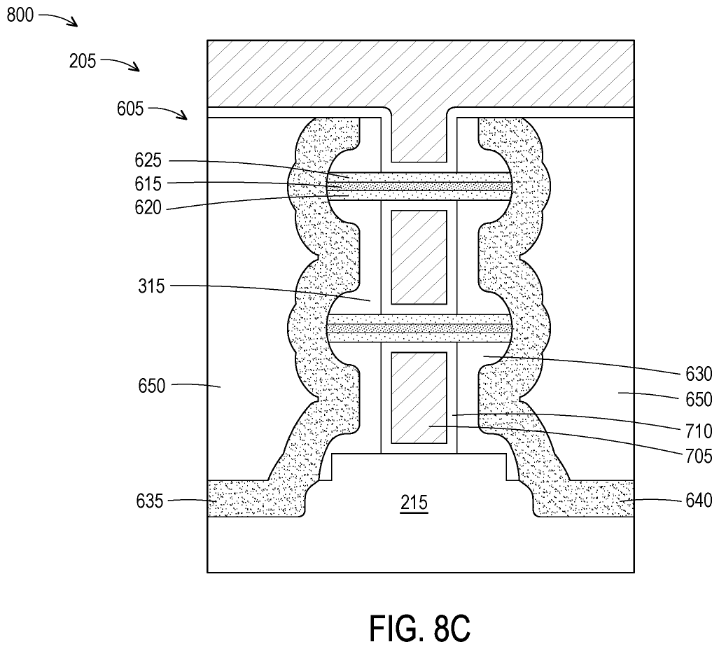

FIGS. 8A-8C are diagrams of an example implementation 800 of an inner spacer formation process described herein. In some implementations, the operations described in connection with the example implementation 800 are performed after the processes described in connection with FIGS. 2A and 2B.

Turning to FIG. 8A, the cavities 305 and the inner spacer layer 310 may be formed in a similar manner as described in connection with FIGS. 3A and 3B, respectively. As shown in FIG. 8A, the inner spacer layer 310 is partially removed such that remaining portions of the inner spacer layer 310 correspond to the inner spacers 315 in the cavities 305. An etch tool 108 may be used to perform an etch operation 805 to partially remove the inner spacer layer 310 to form the inner spacers 315.

The etch operation 805 may include the use of an etchant to perform a less directional etch than the etch operation 320 performed in connection with the example implementation 300. This results in rounding of the ends of the inner spacers 315. In some implementations, a dry etch technique is used, such as a plasma-based etch technique, in which a pressure, a bias voltage, and/or another parameter of the etch tool 108 is selected to achieve the rounding of the ends of the inner spacers 315. In some implementations, another etch technique such as a wet etch technique (e.g., using a wet chemical etchant) is used.

As shown in FIG. 8B, similar operations as illustrated and described in connection with FIGS. 4-6 may be performed to form additional structures and/or layers of the nanostructure transistors 605 after formation of the inner spacers 315.

As further shown in a detailed view in FIG. 8B, the less directional etch results in the inner spacers 315 (and thus, the inner spacers 630) having rounded or curved outer surfaces 810. An outer surface 810 of an inner spacer 630 may have an angle (indicated in FIG. 8B as the dimension D4) that is less than approximately 90 degrees, and that is less than approximately 85 degrees, in some implementations. However, other values for the angle are within the scope of the present disclosure. Moreover, the inner spacers 630 may be recessed relative to an end surface 815 of the nanostructure channels 610 of the nanostructure transistors 605.

As shown in FIG. 8C, similar operations as illustrated and described in connection with FIGS. 7A-7C may be performed to form additional structures and/or layers of the nanostructure transistors 605.

In some implementations, only a bottom supporting dielectric layer 615 is included between a nanostructure channel 610 and an underlying gate structure 705, and a top supporting dielectric layer 620 is omitted from the semiconductor device 205. In these implementations, the top surface of the nanostructure channel 610 may be in direct physical contact with a gate dielectric layer 710 between the nanostructure channel 610 and a gate structure 705 above the nanostructure channel 610. In some implementations, only a top supporting dielectric layer 620 is included between a nanostructure channel 610 and a gate structure 705 above the nanostructure channel 610, and the bottom supporting dielectric layer 615 is omitted from the semiconductor device 205. In these implementations, the bottom surface of the nanostructure channel 610 may be in direct physical contact with a gate dielectric layer 710 between the nanostructure channel 610 and a gate structure 705 under the nanostructure channel 610.

As indicated above, FIGS. 8A-8C are provided as an example. Other examples may differ from what is described with regard to FIGS. 8A-8C. Example implementation 800 may include additional operations, fewer operations, different operations, and/or a different order of operations than those described in connection with FIGS. 8A-8C.

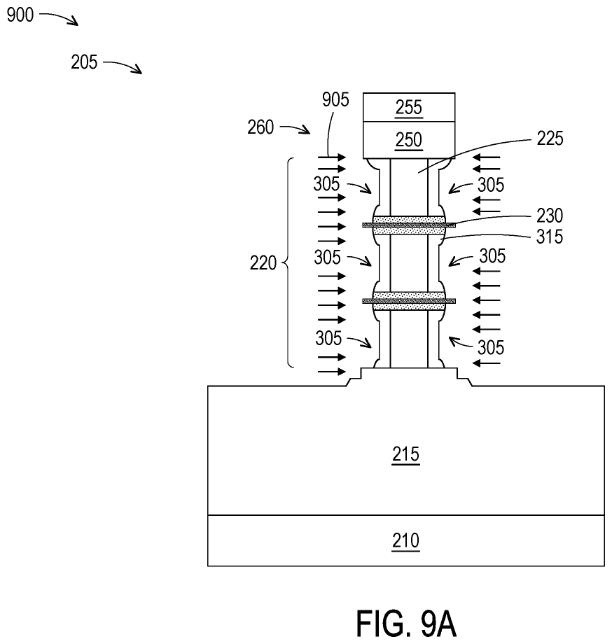

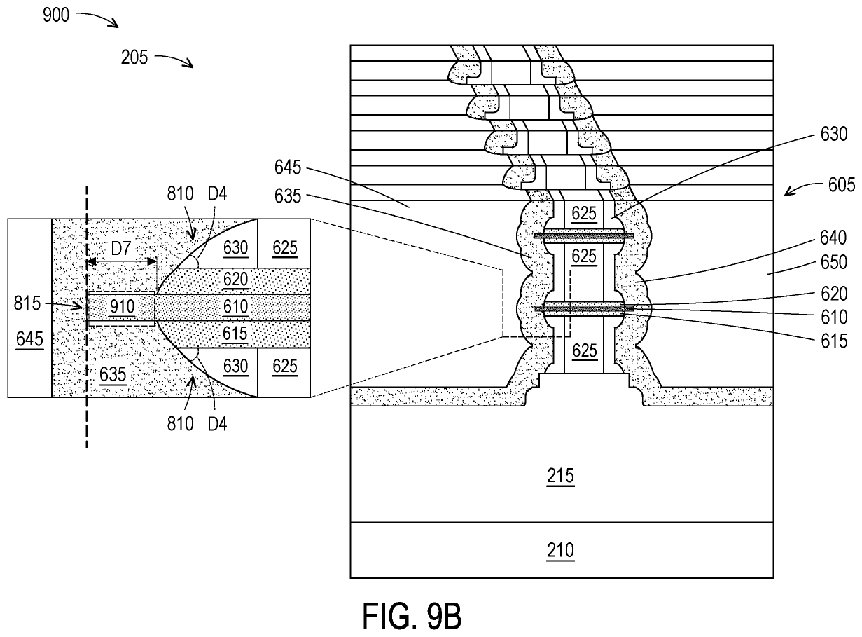

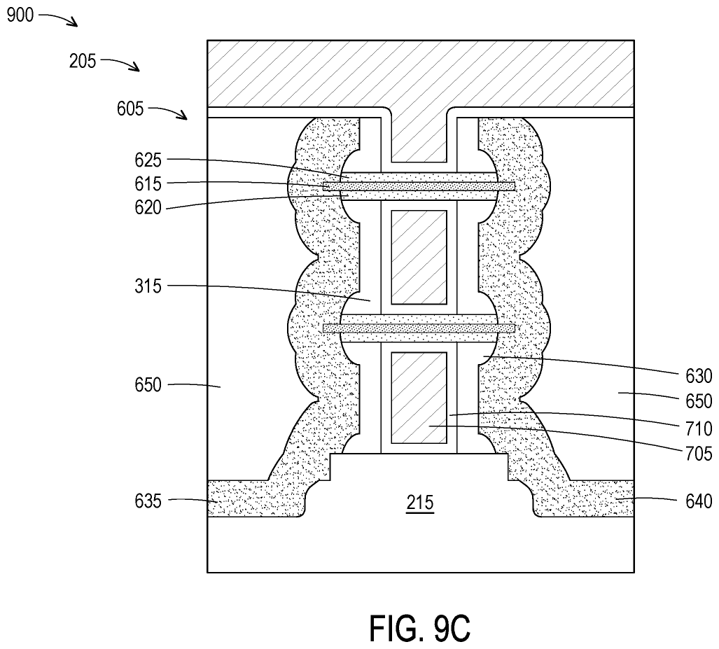

FIGS. 9A-9C are diagrams of an example implementation 900 of an inner spacer formation process described herein. In some implementations, the operations described in connection with the example implementation 900 are performed after the processes described in connection with FIGS. 2A and 2B.

Turning to FIG. 9A, the cavities 305 and the inner spacer layer 310 may be formed in a similar manner as described in connection with FIGS. 3A and 3B, respectively. As shown in FIG. 9A, the inner spacer layer 310 is partially removed such that remaining portions of the inner spacer layer 310 correspond to the inner spacers 315 in the cavities 305. An etch tool 108 may be used to perform an etch operation 905 to partially remove the inner spacer layer 310 to form the inner spacers 315. The etch operation 905 may include the use of a lateral etch technique (e.g., as opposed to a vertical etch technique used in the etch operation 320). In the etch operation 905, a plasma, a hydrofluoric acid (HF) vapor, and/or another type of etchant is used to laterally etch the inner spacer layer 310. One or more parameters such as a pressure, plasma bias voltage, and/or another parameter of the etch tool 108 are selected to achieve the lateral etch of the inner spacers 315.

As further shown in FIG. 9A, the lateral etch of the inner spacer layer 310 also results in lateral etching of the bottom supporting dielectric layers 240 and/or lateral etching of the top supporting dielectric layers 245. The lateral etching of the bottom supporting dielectric layers 240 and/or of the top supporting dielectric layers 245 results in ends of the nanostructure channel layers 235 extending laterally outward past the bottom supporting dielectric layers 240 and/or the top supporting dielectric layers 245. In some implementations, the etchant used for the etch operation 905 is less selective with respect to etching the bottom supporting dielectric layers 240 and the top supporting dielectric layers 245, resulting in the etching of the bottom supporting dielectric layers 240 and the top supporting dielectric layers 245.

As shown in FIG. 9B, similar operations as illustrated and described in connection with FIGS. 4-6 may be performed to form additional structures and/or layers of the nanostructure transistors 605 after formation of the inner spacers 315.

As further shown in a detailed view in FIG. 9B, the lateral etch of the etch operation 905 results in the inner spacers 315 (and thus, the inner spacers 630) having rounded or curved outer surfaces 810. An outer surface 810 of an inner spacer 630 may have an angle (indicated in FIG. 9B as the dimension D4) that is less than approximately 90 degrees, and that is less than approximately 85 degrees, in some implementations. However, other values for the angle are within the scope of the present disclosure. Moreover, the inner spacers 630 may be recessed relative to an end surface 815 of the nanostructure channels 610 of the nanostructure transistors 605. The ends of the bottom supporting dielectric layers 615 and the top supporting dielectric layers 620 may also be curved, and the inner spacers 630 may be recessed relative to the ends of the bottom supporting dielectric layers 615 and the top supporting dielectric layers 620.

In addition, ends 910 of the nanostructure channels 610 extend laterally outward past the bottom supporting dielectric layers 615 and the top supporting dielectric layers 620. A distance (corresponding to dimension D7 in FIG. 9B) between an end surface 815 of a nanostructure channel 610 and a bottom supporting dielectric layer 615 or a top supporting dielectric layer 620 may be included in a range of approximately 2 nanometers to approximately 10 nanometers. The end 910 of the nanostructure channel 610 may protrude laterally outward past the bottom supporting dielectric layers 615 and the top supporting dielectric layers 620 by this distance to enable the source/drain contact 635 or the source/drain contact 640 to wrap around the end 910. This provides increased physical contact between the end 910 of the nanostructure channel 610 and the source/drain contact 635 or the source/drain contact 640, which may reduce contact resistance between the nanostructure channel 610 and the source/drain contact 635 or the source/drain contact 640. However, other values for the range are within the scope of the present disclosure.

As shown in FIG. 9C, similar operations as illustrated and described in connection with FIGS. 7A-7C may be performed to form additional structures and/or layers of the nanostructure transistors 605.

In some implementations, only a bottom supporting dielectric layer 615 is included between a nanostructure channel 610 and an underlying gate structure 705, and a top supporting dielectric layer 620 is omitted from the semiconductor device 205. In these implementations, the top surface of the nanostructure channel 610 may be in direct physical contact with a gate dielectric layer 710 between the nanostructure channel 610 and a gate structure 705 above the nanostructure channel 610. In some implementations, only a top supporting dielectric layer 620 is included between a nanostructure channel 610 and a gate structure 705 above the nanostructure channel 610, and the bottom supporting dielectric layer 615 is omitted from the semiconductor device 205. In these implementations, the bottom surface of the nanostructure channel 610 may be in direct physical contact with a gate dielectric layer 710 between the nanostructure channel 610 and a gate structure 705 under the nanostructure channel 610.

As indicated above, FIGS. 9A-9C are provided as an example. Other examples may differ from what is described with regard to FIGS. 9A-9C. Example implementation 900 may include additional operations, fewer operations, different operations, and/or a different order of operations than those described in connection with FIGS. 9A-9C.

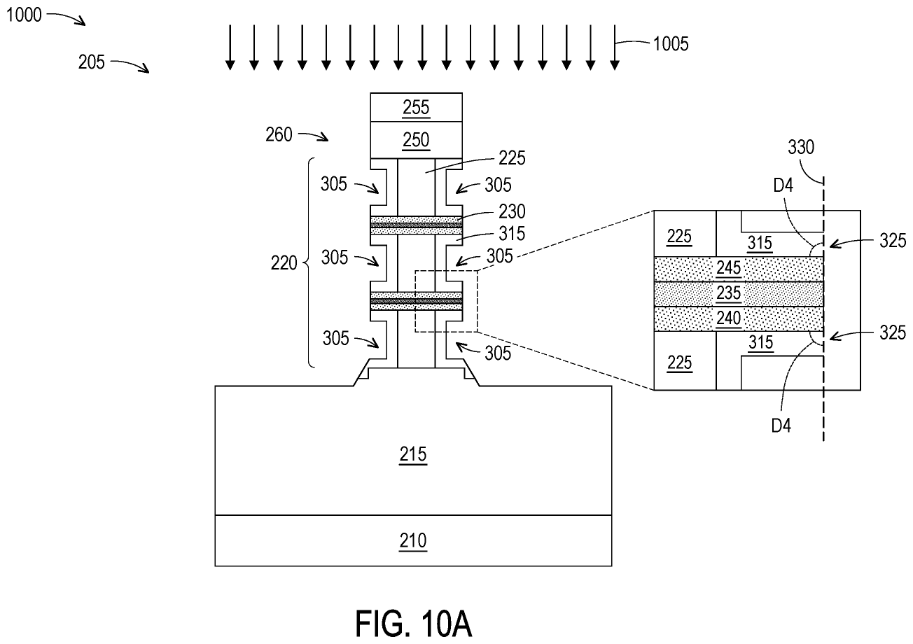

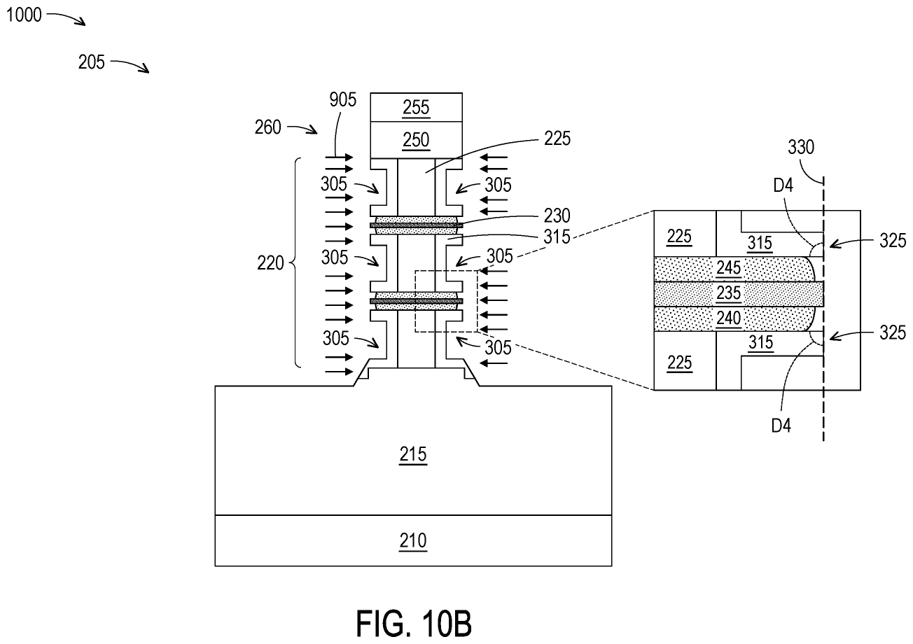

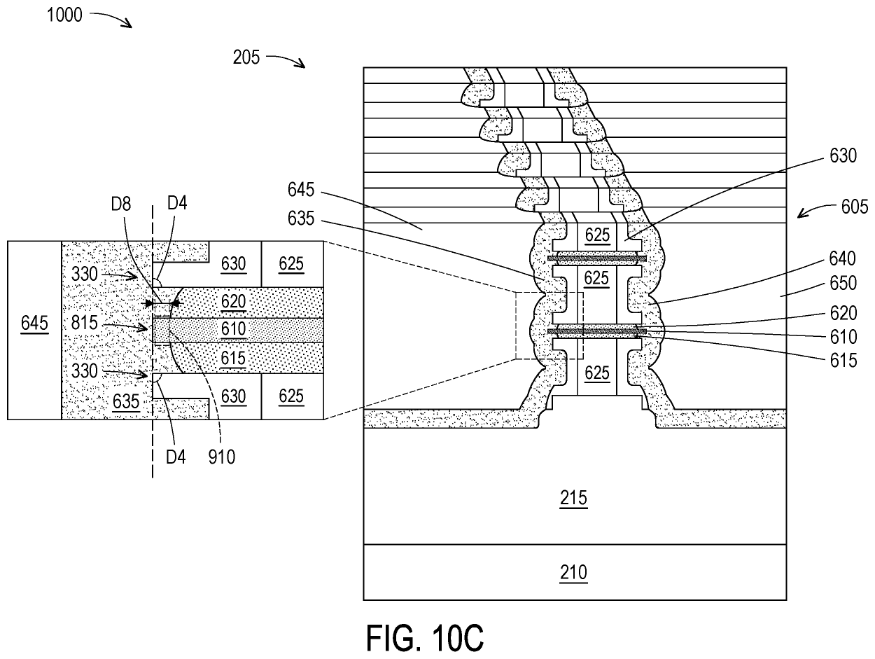

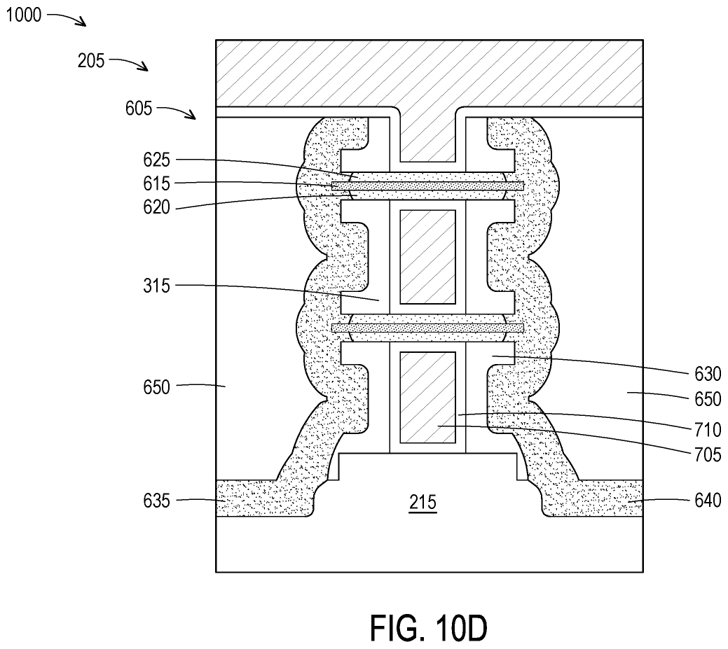

FIGS. 10A-10D are diagrams of an example implementation 1000 of an inner spacer formation process described herein. In some implementations, the operations described in connection with the example implementation 1000 are performed after the processes described in connection with FIGS. 2A and 2B.

Turning to FIG. 10A, the cavities 305 and the inner spacer layer 310 may be formed in a similar manner as described in connection with FIGS. 3A and 3B, respectively. As shown in FIG. 10A, the inner spacer layer 310 is partially removed such that remaining portions of the inner spacer layer 310 correspond to the inner spacers 315 in the cavities 305. An etch tool 108 may be used to perform an etch operation 1005 to partially remove the inner spacer layer 310 to form the inner spacers 315. The etch operation 1005 may include the use of a vertical etch technique, similar to the etch operation 320 described in connection with FIGS. 3A-3D.

As shown in a detailed view in FIG. 10A, ends 325 of the inner spacers 315 may be approximately co-planar with ends of the channel layer stack 230 (e.g., with ends of the nanostructure channel layer 235, the bottom supporting dielectric layer 240, and/or the top supporting dielectric layer 245) in that the ends 325 of the inner spacers 315 and the ends of the channel layer stack 230 are approximately in a same horizontal plane 330. The ends 325 of the inner spacers 315 may have an angle (indicated in FIG. 10A as dimension D4) relative to the nanostructure channel layer 235, the bottom supporting dielectric layer 240, and/or the top supporting dielectric layer 245, that is approximately 90 degrees (e.g., approximately 85-95 degrees). However, other values for the angle are within the scope of the present disclosure.

As shown in FIG. 10B, an etch tool 108 may be used to perform another etch operation 1010 to etch ends 1015 of the bottom supporting dielectric layers 240 and the top supporting dielectric layers 245. The etch operation 1010 may include the use of a lateral etch technique (e.g., as opposed to a vertical etch technique used in the etch operation 1005). In the etch operation 1010, a plasma, a hydrofluoric acid (HF) vapor, a wet etch, and/or another type of etchant is used to laterally etch the ends 1015 of the bottom supporting dielectric layers 240 and the top supporting dielectric layers 245. An etchant used in the etch operation 1010 may have a high etch rate for the bottom supporting dielectric layers 240 and the top supporting dielectric layers 245, and a low etch rate for the inner spacers 315 and the nanostructure channel layers 235.

As further shown in FIG. 10B, the lateral etch of the ends 1015 of the bottom supporting dielectric layers 240 and the top supporting dielectric layers 245 results in ends of the nanostructure channel layers 235 extending laterally outward past the bottom supporting dielectric layers 240 and/or the top supporting dielectric layers 245. The ends 325 of the inner spacers 315 and the ends of the nanostructure channel layers 235 may remain in approximately the same horizontal plane 330 due to the etch selectivity of the etchant used in the etch operation 1010.

As shown in FIG. 10C, similar operations as illustrated and described in connection with FIGS. 4-6 may be performed to form additional structures and/or layers of the nanostructure transistors 605 after formation of the inner spacers 315.

As further shown in a detailed view in FIG. 10C, the vertical etch of the etch operation 1005 results in the inner spacers 315 (and thus, the inner spacers 630) having approximately straight and right-angled ends 325. In addition, the lateral etch of the etch operation 1010 results in the ends 910 of the nanostructure channels 610 extending laterally outward past the bottom supporting dielectric layers 615 and the top supporting dielectric layers 620. A distance (corresponding to dimension D8 in FIG. 9B) between an end surface 815 of a nanostructure channel 610 and a bottom supporting dielectric layer 615 or a top supporting dielectric layer 620 may be included in a range of approximately 2 nanometers to approximately 10 nanometers. The end 910 of the nanostructure channel 610 may protrude laterally outward past the bottom supporting dielectric layers 615 and the top supporting dielectric layers 620 by this distance to enable the source/drain contact 635 or the source/drain contact 640 to wrap around the end 910. This provides increased physical contact between the end 910 of the nanostructure channel 610 and the source/drain contact 635 or the source/drain contact 640, which may reduce contact resistance between the nanostructure channel 610 and the source/drain contact 635 or the source/drain contact 640. However, other values for the range are within the scope of the present disclosure.

As shown in FIG. 10D, similar operations as illustrated and described in connection with FIGS. 7A-7C may be performed to form additional structures and/or layers of the nanostructure transistors 605.

In some implementations, only a bottom supporting dielectric layer 615 is included between a nanostructure channel 610 and an underlying gate structure 705, and a top supporting dielectric layer 620 is omitted from the semiconductor device 205. In these implementations, the top surface of the nanostructure channel 610 may be in direct physical contact with a gate dielectric layer 710 between the nanostructure channel 610 and a gate structure 705 above the nanostructure channel 610. In some implementations, only a top supporting dielectric layer 620 is included between a nanostructure channel 610 and a gate structure 705 above the nanostructure channel 610, and the bottom supporting dielectric layer 615 is omitted from the semiconductor device 205. In these implementations, the bottom surface of the nanostructure channel 610 may be in direct physical contact with a gate dielectric layer 710 between the nanostructure channel 610 and a gate structure 705 under the nanostructure channel 610.

As indicated above, FIGS. 10A-10D are provided as an example. Other examples may differ from what is described with regard to FIGS. 10A-10D. Example implementation 1000 may include additional operations, fewer operations, different operations, and/or a different order of operations than those described in connection with FIGS. 10A-10D.

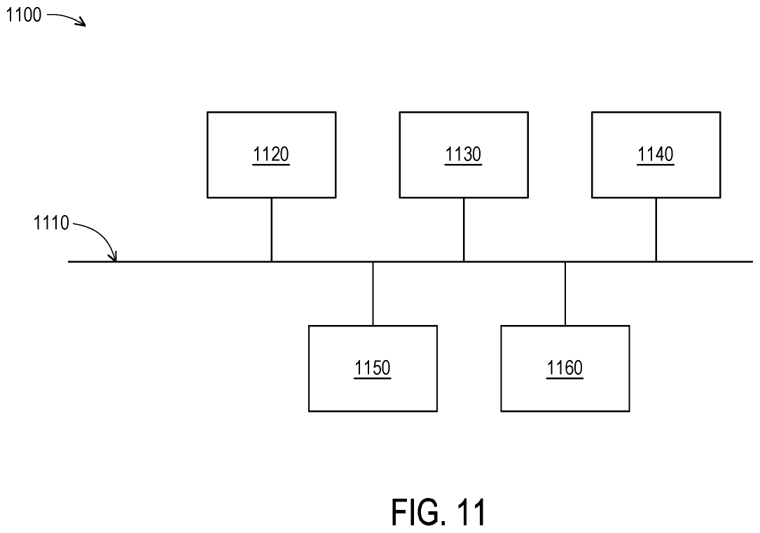

FIG. 11 is a diagram of example components of a device 1100 described herein. In some implementations, one or more of the semiconductor processing tools 102-112 and/or the wafer/die transport tool 114 may include one or more devices 1100 and/or one or more components of the device 1100. As shown in FIG. 11, the device 1100 may include a bus 1110, a processor 1120, a memory 1130, an input component 1140, an output component 1150, and/or a communication component 1160.

The bus 1110 may include one or more components that enable wired and/or wireless communication among the components of the device 1100. The bus 1110 may couple together two or more components of FIG. 11, such as via operative coupling, communicative coupling, electronic coupling, and/or electric coupling. For example, the bus 1110 may include an electrical connection (e.g., a wire, a trace, and/or a lead) and/or a wireless bus. The processor 1120 may include a central processing unit, a graphics processing unit, a microprocessor, a controller, a microcontroller, a digital signal processor, a field-programmable gate array, an application-specific integrated circuit, and/or another type of processing component. The processor 1120 may be implemented in hardware, firmware, or a combination of hardware and software. In some implementations, the processor 1120 may include one or more processors capable of being programmed to perform one or more operations or processes described elsewhere herein.

The memory 1130 may include volatile and/or nonvolatile memory. For example, the memory 1130 may include random access memory (RAM), read only memory (ROM), a hard disk drive, and/or another type of memory (e.g., a flash memory, a magnetic memory, and/or an optical memory). The memory 1130 may include internal memory (e.g., RAM, ROM, or a hard disk drive) and/or removable memory (e.g., removable via a universal serial bus connection). The memory 1130 may be a non-transitory computer-readable medium. The memory 1130 may store information, one or more instructions, and/or software (e.g., one or more software applications) related to the operation of the device 1100. In some implementations, the memory 1130 may include one or more memories that are coupled (e.g., communicatively coupled) to one or more processors (e.g., processor 1120), such as via the bus 1110. Communicative coupling between a processor 1120 and a memory 1130 may enable the processor 1120 to read and/or process information stored in the memory 1130 and/or to store information in the memory 1130.

The input component 1140 may enable the device 1100 to receive input, such as user input and/or sensed input. For example, the input component 1140 may include a touch screen, a keyboard, a keypad, a mouse, a button, a microphone, a switch, a sensor, a global positioning system sensor, a global navigation satellite system sensor, an accelerometer, a gyroscope, and/or an actuator. The output component 1150 may enable the device 1100 to provide output, such as via a display, a speaker, and/or a light-emitting diode. The communication component 1160 may enable the device 1100 to communicate with other devices via a wired connection and/or a wireless connection. For example, the communication component 1160 may include a receiver, a transmitter, a transceiver, a modem, a network interface card, and/or an antenna.

The device 1100 may perform one or more operations or processes described herein. For example, a non-transitory computer-readable medium (e.g., memory 1130) may store a set of instructions (e.g., one or more instructions or code) for execution by the processor 1120. The processor 1120 may execute the set of instructions to perform one or more operations or processes described herein. In some implementations, execution of the set of instructions, by one or more processors 1120, causes the one or more processors 1120 and/or the device 1100 to perform one or more operations or processes described herein. In some implementations, hardwired circuitry may be used instead of or in combination with the instructions to perform one or more operations or processes described herein. Additionally, or alternatively, the processor 1120 may be configured to perform one or more operations or processes described herein. Thus, implementations described herein are not limited to any specific combination of hardware circuitry and software.

The number and arrangement of components shown in FIG. 11 are provided as an example. The device 1100 may include additional components, fewer components, different components, or differently arranged components than those shown in FIG. 11. Additionally, or alternatively, a set of components (e.g., one or more components) of the device 1100 may perform one or more functions described as being performed by another set of components of the device 1100.

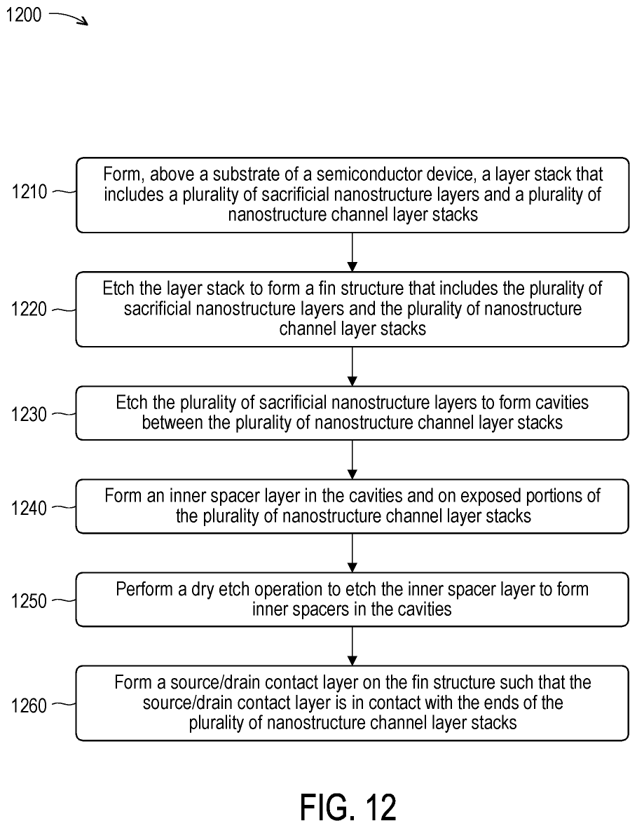

FIG. 12 is a flowchart of an example process 1200 associated with forming a semiconductor device described herein. In some implementations, one or more process blocks of FIG. 12 are performed using one or more semiconductor processing tools (e.g., one or more of the semiconductor processing tools 102-112). Additionally, or alternatively, one or more process blocks of FIG. 12 may be performed using one or more components of device 1100, such as processor 1120, memory 1130, input component 1140, output component 1150, and/or communication component 1160.

As shown in FIG. 12, process 1200 may include forming, above a substrate of a semiconductor device, a layer stack that includes a plurality of sacrificial nanostructure layers and a plurality of nanostructure channel layer stacks (block 1210). For example, one or more of the semiconductor processing tools 102-112 may be used to form, above a semiconductor substrate 210 of a semiconductor device 205, a layer stack 220 that includes a plurality of sacrificial nanostructure layers 225 and a plurality of channel layer stacks 230, as described herein. In some implementations, the plurality of sacrificial nanostructure layers 225 and the plurality of channel layer stacks 230 are arranged in a direction that is approximately perpendicular to the semiconductor substrate 210. In some implementations, a channel layer stack 230, of the plurality of channel layer stacks 230, includes a nanostructure channel layer 235 and at least one supporting dielectric layer (e.g., a bottom supporting dielectric layer 240, a top supporting dielectric layer 245) between the nanostructure channel layer 235 and a sacrificial nanostructure layer 225 of the plurality of sacrificial nanostructure layers 225.

As further shown in FIG. 12, process 1200 may include etching the layer stack to form a fin structure that includes the plurality of sacrificial nanostructure layers and the plurality of nanostructure channel layer stacks (block 1220). For example, one or more of the semiconductor processing tools 102-112 may be used to etch the layer stack 220 to form a fin structure 260 that includes the plurality of sacrificial nanostructure layers 225 and the plurality of channel layer stacks 230, as described herein.

As further shown in FIG. 12, process 1200 may include etching the plurality of sacrificial nanostructure layers to form cavities between the plurality of nanostructure channel layer stacks (block 1230). For example, one or more of the semiconductor processing tools 102-112 may be used to etch the plurality of sacrificial nanostructure layers 225 to form cavities 305 between the plurality of channel layer stacks 230, as described herein.

As further shown in FIG. 12, process 1200 may include forming an inner spacer layer in the cavities and on exposed portions of the plurality of nanostructure channel layer stacks (block 1240). For example, one or more of the semiconductor processing tools 102-112 may be used to form an inner spacer layer 310 in the cavities 305 and on exposed portions of the plurality of channel layer stacks 230, as described herein.

As further shown in FIG. 12, process 1200 may include performing a dry etch operation to etch the inner spacer layer to form inner spacers in the cavities (block 1250). For example, one or more of the semiconductor processing tools 102-112 may be used to perform a dry etch operation (e.g., an etch operation 320, an etch operation 1005) to etch the inner spacer layer 310 to form inner spacers 315 in the cavities 305, as described herein. In some implementations, the dry etch operation results in ends of the plurality of channel layer stacks 230 being exposed.

As further shown in FIG. 12, process 1200 may include forming a source/drain contact layer on the fin structure such that the source/drain contact layer is in contact with the ends of the plurality of nanostructure channel layer stacks (block 1260). For example, one or more of the semiconductor processing tools 102-112 may be used to form a source/drain contact layer 405 on the fin structure 260 such that the source/drain contact layer 405 is in contact with the ends of the plurality of channel layer stacks 230, as described herein.

Process 1200 may include additional implementations, such as any single implementation or any combination of implementations described below and/or in connection with one or more other processes described elsewhere herein.

In a first implementation, an end of the nanostructure channel layer 235, an end of the at least one supporting dielectric layer (e.g., an end of a bottom supporting dielectric layer 240, an end of a top supporting dielectric layer 245), and ends 325 of a subset of the inner spacers 315 adjacent to the channel layer stack 230 are approximately co-planar.

In a second implementation, alone or in combination with the first implementation, process 1200 includes performing, using a wet etchant, a wet etch operation (e.g., an etch operation 1010) after the dry etch operation to etch the at least one supporting layer.

In a third implementation, alone or in combination with one or more of the first and second implementations, an end 1015 of the at least one supporting dielectric layer (e.g., an end 1015 of a bottom supporting dielectric layer 240, an end 1015 of a top supporting dielectric layer 245) is recessed relative to an end of the nanostructure channel layer 235, and ends 325 of a subset of the inner spacers 315 adjacent to the channel layer stack 230 are approximately co-planar.

In a fourth implementation, alone or in combination with one or more of the first through third implementations, the end of the at least one supporting dielectric layer is curved.

In a fifth implementation, alone or in combination with one or more of the first through fourth implementations, the end of the nanostructure channel layer and the ends of the subset of the inner spacers adjacent to the nanostructure channel layer stack are approximately co-planar.

In a sixth implementation, alone or in combination with one or more of the first through fifth implementations, an etch rate of the supporting dielectric layer is greater than an etch rate of the wet etchant for the nanostructure channel layer and an etch rate of the wet etchant for the subset of the inner spacers adjacent to the nanostructure channel layer stack.

Although FIG. 12 shows example blocks of process 1200, in some implementations, process 1200 includes additional blocks, fewer blocks, different blocks, or differently arranged blocks than those depicted in FIG. 12. Additionally, or alternatively, two or more of the blocks of process 1200 may be performed in parallel.

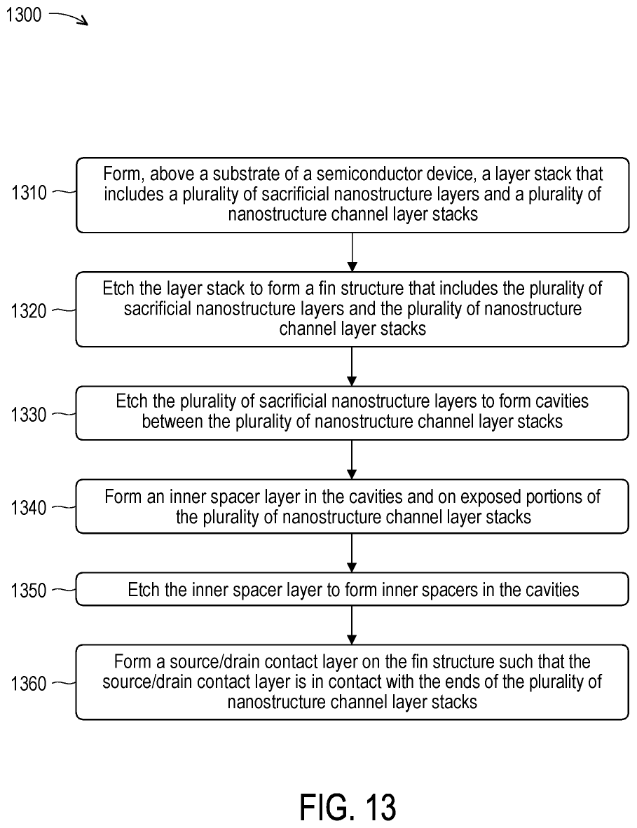

FIG. 13 is a flowchart of an example process 1300 associated with forming a semiconductor device described herein. In some implementations, one or more process blocks of FIG. 13 are performed using one or more semiconductor processing tools (e.g., one or more of the semiconductor processing tools 102-112). Additionally, or alternatively, one or more process blocks of FIG. 13 may be performed using one or more components of device 1100, such as processor 1120, memory 1130, input component 1140, output component 1150, and/or communication component 1160.

As shown in FIG. 13, process 1300 may include forming, above a substrate of a semiconductor device, a layer stack that includes a plurality of sacrificial nanostructure layers and a plurality of nanostructure channel layer stacks (block 1310). For example, one or more of the semiconductor processing tools 102-112 may be used to form, above a semiconductor substrate 210 of a semiconductor device 205, a layer stack 220 that includes a plurality of sacrificial nanostructure layers 225 and a plurality of channel layer stacks 230, as described herein. In some implementations, the plurality of sacrificial nanostructure layers 225 and the plurality of channel layer stacks 230 are arranged in a direction that is approximately perpendicular to the semiconductor substrate 210. In some implementations, a channel layer stack 230, of the plurality of channel layer stacks 230, includes a nanostructure channel layer 235 and at least one supporting dielectric layer (e.g., a bottom supporting dielectric layer 240, a top supporting dielectric layer 245) between the nanostructure channel layer 235 and a sacrificial nanostructure layer 225 of the plurality of sacrificial nanostructure layers 225.

As further shown in FIG. 13, process 1300 may include etching the layer stack to form a fin structure that includes the plurality of sacrificial nanostructure layers and the plurality of nanostructure channel layer stacks (block 1320). For example, one or more of the semiconductor processing tools 102-112 may be used to etch the layer stack 220 to form a fin structure 260 that includes the plurality of sacrificial nanostructure layers 225 and the plurality of channel layer stacks 230, as described herein.

As further shown in FIG. 13, process 1300 may include etching the plurality of sacrificial nanostructure layers to form cavities between the plurality of nanostructure channel layer stacks (block 1330). For example, one or more of the semiconductor processing tools 102-112 may be used to etch the plurality of sacrificial nanostructure layers 225 to form cavities 305 between the plurality of channel layer stacks 230, as described herein.

As further shown in FIG. 13, process 1300 may include forming an inner spacer layer in the cavities and on exposed portions of the plurality of nanostructure channel layer stacks (block 1340). For example, one or more of the semiconductor processing tools 102-112 may be used to form an inner spacer layer 310 in the cavities 305 and on exposed portions of the plurality of channel layer stacks 230, as described herein.

As further shown in FIG. 13, process 1300 may include etching the inner spacer layer to form inner spacers in the cavities (block 1350). For example, one or more of the semiconductor processing tools 102-112 may be used to etch the inner spacer layer 310 to form inner spacers 315 in the cavities 305, as described herein. In some implementations, etching the inner spacer layer 310 results in ends of the plurality of channel layer stacks 230 being exposed. In some implementations, the inner spacers 315 have a curved outer surface 810.

As further shown in FIG. 13, process 1300 may include forming a source/drain contact layer on the fin structure such that the source/drain contact layer is in contact with the ends of the plurality of nanostructure channel layer stacks (block 1360). For example, one or more of the semiconductor processing tools 102-112 may be used to form a source/drain contact layer 405 on the fin structure 260 such that the source/drain contact layer 405 is in contact with the ends of the plurality of channel layer stacks 230, as described herein.

Process 1300 may include additional implementations, such as any single implementation or any combination of implementations described below and/or in connection with one or more other processes described elsewhere herein.

In a first implementation, an end of the at least one supporting dielectric layer (e.g., an end of a bottom supporting dielectric layer 240, an end of a top supporting dielectric layer 245) is curved.

In a second implementation, alone or in combination with the first implementation, an end of the at least one supporting dielectric layer (e.g., an end of a bottom supporting dielectric layer 240, an end of a top supporting dielectric layer 245) and an end of the nanostructure channel layer 235 are approximately co-planar.

In a third implementation, alone or in combination with one or more of the first and second implementations, an end of the nanostructure channel layer 235 extends laterally outward from an end of the at least one supporting dielectric layer (e.g., an end of a bottom supporting dielectric layer 240, an end of a top supporting dielectric layer 245).

In a fourth implementation, alone or in combination with one or more of the first through third implementations, etching the inner spacer layer 310 includes performing a wet etch operation to etch the inner spacer layer 310.

In a fifth implementation, alone or in combination with one or more of the first through fourth implementations, etching the inner spacer layer 310 includes performing a lateral plasma etching operation to etch the inner spacer layer 310.

In a sixth implementation, alone or in combination with one or more of the first through fifth implementations, etching the inner spacer layer 310 includes performing a lateral hydrofluoric acid etching operation to etch the inner spacer layer 310.

Although FIG. 13 shows example blocks of process 1300, in some implementations, process 1300 includes additional blocks, fewer blocks, different blocks, or differently arranged blocks than those depicted in FIG. 13. Additionally, or alternatively, two or more of the blocks of process 1300 may be performed in parallel.

In this way, one or more supporting dielectric layers are included under and/or on a nanostructure channel of a nanostructure transistor. The nanostructure transistor may be formed by forming a nanosheet stack that includes one or more channel layer stacks that are sandwiched between sacrificial layers. The nanostructure channel layer stacks may each include a nanostructure channel layer and one or more dielectric supporting layers under and/or on the nanostructure channel layer. The nanosheet stack is etched to define the nanostructure channels of the nanostructure transistor. An inner spacer process is performed to form inner spacers on sidewalls of the sacrificial layers between the nanostructure channel layer stacks, and source/drain contacts are then formed on sidewalls of the nanostructure channel layer stacks and on the inner spacers. The sacrificial layers are subsequently removed in a nanosheet release process and replaced with a metal gate structure and associated high-k dielectric layers.

The supporting dielectric layer(s) may increase the mechanical strength of the nanostructure channel, which enables advanced materials such as TMD materials to be used in the nanostructure channel. This enables two-dimensional nanostructure channels (e.g., nanostructure channels that are approximately one atom in thickness) to be realized in the nanostructure transistor. Additionally and/or alternatively, the supporting dielectric layer(s) may reduce the likelihood and/or magnitude of mechanical degradation of the nanostructure channel that might otherwise occur due to external forces from subsequent semiconductor processing operations such as film patterning and/or nanosheet release, among other examples. Thus, the supporting dielectric layer(s) may provide a greater process window (e.g., a greater temperature range, a greater mechanical stress range) for forming the nanostructure channel. The supporting dielectric layer(s) may also provide a substrate on which the high-k dielectric layers of the metal gate structure are deposited, which may decrease void formation and improve thin-film growth of the high-k dielectric layers, relative to forming the high-k dielectric layers only on the two-dimensional nanostructure channels. The supporting dielectric layer(s) may increase the structural strength of a vertical stack of nanostructure channels, thereby enabling a great quantity of nanostructure channels to be realized on a single vertical stack. The supporting dielectric layer(s) may also provide sufficient structural strength for the nanostructure channel to enable the nanostructure channel to extend laterally outward from the supporting dielectric layer(s), which may enable reduced contact resistance to be achieved between the nanostructure channel and a source/drain contact in that a greater contact area between the nanostructure channel and the source/drain contact can be achieved. Moreover, the process for forming the supporting dielectric layer(s) may be integrated with silicon (Si) processing operations.

As described in greater detail above, some implementations described herein provide a method. The method includes forming, above a substrate of a semiconductor device, a layer stack that includes a plurality of sacrificial nanostructure layers and a plurality of nanostructure channel layer stacks, where the plurality of sacrificial nanostructure layers and the plurality of nanostructure channel layer stacks are arranged in a direction that is approximately perpendicular to the substrate, and where a nanostructure channel layer stack, of the plurality of nanostructure channel layer stacks, includes a nanostructure channel layer and at least one supporting dielectric layer between the nanostructure channel layer and a sacrificial nanostructure layer of the plurality of sacrificial nanostructure layers. The method includes etching the layer stack to form a fin structure that includes the plurality of sacrificial nanostructure layers and the plurality of nanostructure channel layer stacks. The method includes etching the plurality of sacrificial nanostructure layers to form cavities between the plurality of nanostructure channel layer stacks. The method includes forming an inner spacer layer in the cavities and on exposed portions of the plurality of nanostructure channel layer stacks. The method includes performing a dry etch operation to etch the inner spacer layer to form inner spacers in the cavities, where the dry etch operation results in ends of the plurality of nanostructure channel layer stacks being exposed. The method includes forming a source/drain contact layer on the fin structure such that the source/drain contact layer is in contact with the ends of the plurality of nanostructure channel layer stacks.

As described in greater detail above, some implementations described herein provide a method. The method includes forming, above a substrate of a semiconductor device, a layer stack that includes a plurality of sacrificial nanostructure layers and a plurality of nanostructure channel layer stacks, where the plurality of sacrificial nanostructure layers and the plurality of nanostructure channel layer stacks are arranged in a direction that is approximately perpendicular to the substrate, and where a nanostructure channel layer stack, of the plurality of nanostructure channel layer stacks, includes a nanostructure channel layer and at least one supporting dielectric layer between the nanostructure channel layer and a sacrificial nanostructure layer of the plurality of sacrificial nanostructure layers. The method includes etching the layer stack to form a fin structure that includes the plurality of sacrificial nanostructure layers and the plurality of nanostructure channel layer stacks. The method includes etching the plurality of sacrificial nanostructure layers to form cavities between the plurality of nanostructure channel layer stacks. The method includes forming an inner spacer layer in the cavities and on exposed portions of the plurality of nanostructure channel layer stacks. The method includes etching the inner spacer layer to form inner spacers in the cavities, where etching the inner spacer layer results in ends of the plurality of nanostructure channel layer stacks being exposed, and where the inner spacers have a curved outer surface. The method includes forming a source/drain contact layer on the fin structure such that the source/drain contact layer is in contact with the ends of the plurality of nanostructure channel layer stacks.

As described in greater detail above, some implementations described herein provide a semiconductor device. The semiconductor device includes a plurality of nanostructure channels that are arranged in a direction that is approximately perpendicular to a substrate. The plurality of nanostructure channels include a transition metal dichalcogenide (TMD) material. The semiconductor device includes a supporting dielectric layer vertically adjacent to a nanostructure channel of the plurality of nanostructure channels. A first end of the nanostructure channel extends laterally outward from the supporting dielectric layer, and a second end of the nanostructure channel opposing the first end extends laterally outward from the supporting dielectric layer. The semiconductor device includes a first source/drain contact that is in contact with a plurality of surfaces of the first end. The semiconductor device includes a second source/drain contact that is in contact with a plurality of surfaces of the second end.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

The terms “approximately” and “substantially” can indicate a value of a given quantity that varies within 5% of the value (e.g., +1%, +2%, +3%, +4%, +5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming, above a substrate of a semiconductor device, a layer stack comprising a plurality of sacrificial nanostructure layers and a plurality of nanostructure channel layer stacks,
wherein the plurality of sacrificial nanostructure layers and the plurality of nanostructure channel layer stacks are arranged in a direction that is approximately perpendicular to the substrate, and
wherein a nanostructure channel layer stack, of the plurality of nanostructure channel layer stacks, comprises a nanostructure channel layer and at least one supporting dielectric layer between the nanostructure channel layer and a sacrificial nanostructure layer of the plurality of sacrificial nanostructure layers;
etching the layer stack to form a fin structure that comprises the plurality of sacrificial nanostructure layers and the plurality of nanostructure channel layer stacks;
etching the plurality of sacrificial nanostructure layers to form cavities between the plurality of nanostructure channel layer stacks;
forming an inner spacer layer in the cavities and on exposed portions of the plurality of nanostructure channel layer stacks;
performing a dry etch operation to etch the inner spacer layer to form inner spacers in the cavities,
wherein the dry etch operation results in ends of the plurality of nanostructure channel layer stacks being exposed; and
forming a source/drain contact layer on the fin structure such that the source/drain contact layer is in contact with the ends of the plurality of nanostructure channel layer stacks.

2. The method of claim 1, wherein an end of the nanostructure channel layer, an end of the at least one supporting dielectric layer, and ends of a subset of the inner spacers adjacent to the nanostructure channel layer stack are approximately co-planar.

3. The method of claim 1, further comprising:
performing, using a wet etchant, a wet etch operation after the dry etch operation to etch the at least one supporting layer.

4. The method of claim 3, wherein an end of the at least one supporting dielectric layer is recessed relative to an end of the nanostructure channel layer, and ends of a subset of the inner spacers adjacent to the nanostructure channel layer stack are approximately co-planar.

5. The method of claim 4, wherein the end of the at least one supporting dielectric layer is curved.

6. The method of claim 4, wherein the end of the nanostructure channel layer and the ends of the subset of the inner spacers adjacent to the nanostructure channel layer stack are approximately co-planar.

7. The method of claim 4, wherein an etch rate of the at least one supporting dielectric layer is greater than an etch rate of the wet etchant for the nanostructure channel layer and an etch rate of the wet etchant for the subset of the inner spacers adjacent to the nanostructure channel layer stack.

8. A method, comprising:
forming, above a substrate of a semiconductor device, a layer stack comprising a plurality of sacrificial nanostructure layers and a plurality of nanostructure channel layer stacks,
wherein the plurality of sacrificial nanostructure layers and the plurality of nanostructure channel layer stacks are arranged in a direction that is approximately perpendicular to the substrate, and
wherein a nanostructure channel layer stack, of the plurality of nanostructure channel layer stacks, comprises a nanostructure channel layer and at least one supporting dielectric layer between the nanostructure channel layer and a sacrificial nanostructure layer of the plurality of sacrificial nanostructure layers;
etching the layer stack to form a fin structure that comprises the plurality of sacrificial nanostructure layers and the plurality of nanostructure channel layer stacks;
etching the plurality of sacrificial nanostructure layers to form cavities between the plurality of nanostructure channel layer stacks;
forming an inner spacer layer in the cavities and on exposed portions of the plurality of nanostructure channel layer stacks;
etching the inner spacer layer to form inner spacers in the cavities,
wherein etching the inner spacer layer results in ends of the plurality of nanostructure channel layer stacks being exposed, and
wherein the inner spacers have a curved outer surface; and
forming a source/drain contact layer on the fin structure such that the source/drain contact layer is in contact with the ends of the plurality of nanostructure channel layer stacks.

9. The method of claim 8, wherein an end of the at least one supporting dielectric layer is curved.

10. The method of claim 8, wherein an end of the at least one supporting dielectric layer and an end of the nanostructure channel layer are approximately co-planar.

11. The method of claim 8, wherein an end of the nanostructure channel layer extends laterally outward from an end of the at least one supporting dielectric layer.

12. The method of claim 8, wherein etching the inner spacer layer comprises:
performing a wet etch operation to etch the inner spacer layer.

13. The method of claim 8, wherein etching the inner spacer layer comprises:
performing a lateral plasma etching operation to etch the inner spacer layer.

14. The method of claim 8, wherein etching the inner spacer layer comprises:
performing a lateral hydrofluoric acid etching operation to etch the inner spacer layer.

15. A semiconductor device, comprising:
a plurality of nanostructure channels that are arranged in a direction that is approximately perpendicular to a substrate,
wherein the plurality of nanostructure channels comprise a transition metal dichalcogenide (TMD) material;
a supporting dielectric layer vertically adjacent to a nanostructure channel of the plurality of nanostructure channels,
wherein a first end of the nanostructure channel extends laterally outward from the supporting dielectric layer, and
wherein a second end of the nanostructure channel, opposing the first end, extends laterally outward from the supporting dielectric layer;
a first source/drain contact that is in contact with a plurality of surfaces of the first end; and
a second source/drain contact that is in contact with a plurality of surfaces of the second end.

16. The semiconductor device of claim 15, wherein a distance between the first end of the nanostructure channel and an end of the supporting dielectric layer is included in a range of approximately 2 nanometers to approximately 10 nanometers.

17. The semiconductor device of claim 15, further comprising:
a gate structure that wraps around the plurality of nanostructure channels on at least three sides of the plurality of nanostructure channels; and
a plurality of inner spacers between the gate structure and the first source/drain contact, and between the gate structure and the second source/drain contact.

18. The semiconductor device of claim 17, wherein the plurality of inner spacers have curved outer surfaces.

19. The semiconductor device of claim 17, wherein an inner spacer of the plurality of inner spacers, and a nanostructure channel of the plurality of nanostructure channels, have approximately co-planar ends.

20. The semiconductor device of claim 19, wherein the supporting dielectric layer is under the nanostructure channel.
